(19) United States
(12) Patent Application Publication
(10) Pub. No.: US 2025/0164896 A1
(43) Pub. Date: May 22, 2025

(54) METHOD OF FORMING A PLANARIZATION LAYER INCLUDING EXPOSING AT DIFFERENT TEMPERATURES A PHOTOCURABLE COMPOSITION TO ACTINIC RADIATION

(71) Applicant: Canon Kabushiki Kaisha, Tokyo (JP)

(72) Inventors: Timothy Brian STACHOWIAK, Austin, TX (US); Weijun Liu, Cedar Park, TX (US)

(21) Appl. No.: 18/516,403

(22) Filed: Nov. 21, 2023

(51) Int. Cl. G03F 7/00; C08F 112/08; G03F 7/028

(52) U.S. Cl. CPC G03F 7/70558; C08F 112/08; G03F 7/028

(57) ABSTRACT

A system can include a first radiation exposure station including a first actinic radiation source, a superstrate removal tool, a second radiation exposure station located remotely with respect to the first radiation exposure station, and a controller. The second radiation exposure station can include a second actinic radiation source and a heating means for heating a photocurable composition. The controller can be configured to activate the superstrate removal tool to remove the superstrate after a first radiation exposure within the first radiation exposure station and before a second radiation exposure within the second radiation exposure station, and control the heating means to heat the photocurable composition to the radiation exposure temperature. The system can perform a method that includes radiation exposure at a first temperature and radiation exposure at a second temperature that is greater than an ambient temperature and different from the first temperature.

### FIELD OF THE DISCLOSURE

The present disclosure relates to methods of forming planarization layers including exposing photocurable compositions at different temperatures to actinic radiation.

### RELATED ART

Ink-jet Adaptive Planarization (IAP) is used in microelectronic fabrication. As dimensions of microelectronic components continue to become smaller, processes, including IAP, become more difficult. An IAP process can include dispensing a photocurable composition over a substrate and placing a superstrate in contact with the photocurable composition. The IAP process can further include photocuring a layer of the photocurable composition by exposing the photocurable composition to actinic radiation to form a cured layer. The photocuring is performed at room temperature, for example 20° C. The cured layer is then baked to form a baked planarization layer. The thickness of the baked planarization layer is thinner than the thickness of the photocurable composition. The thickness change reduces the planarization performance of the baked planarization layer formed by the IAP process described above. The resulting surface of the baked planarization layer may have a non-uniform topography that has some areas that are at a locally lower elevation and other areas that are at a locally higher elevation. A planarization layer having no elevational difference or at least less elevational differences across such surface is desired.

Materials used for IAP may take substantially longer to photocure to form a cured planarization layer as compared to a photocuring a patterned resist layer used in nano-imprint lithography (NIL). For example, a planarization layer formed using an IAP process may take minutes to photocure, whereas a patterned resist layer formed using an NIL process can be photocured in less than a second.

A cured polymer layer can be baked at a temperature in a range of 350° C. to 400° C. when forming a planarization layer using an IAP process. Many materials used to form a cured polymer layer used in NIL cannot withstand the baking and will decompose or otherwise be substantially adversely affected by the baking temperature. Thus, many materials used in NIL can be unsuitable for use in an IAP process.

A need exists for obtaining a planarization layer that has no or very little elevational difference across the surface while still maintaining acceptable throughput when forming the planarization layer.

### SUMMARY

In an aspect, a method can include exposing a photocurable composition to a first actinic radiation at a first temperature; and exposing the photocurable composition to a second actinic radiation at a second temperature to form a cured planarization layer, wherein the second temperature is greater than an ambient temperature and different from the first temperature.

In an implementation, the method further includes dispensing the photocurable composition onto a substrate, wherein exposing the photocurable composition to the first actinic radiation is performed such that the photocurable composition is disposed between the substrate and a superstrate.

In a particular implementation, the method further includes removing the superstrate after exposing the photocurable composition to the first actinic radiation and before exposing the photocurable composition to the second actinic radiation.

In another embodiment, exposing the photocurable composition to the first actinic radiation and exposing the photocurable composition to the second actinic radiation is performed such that the second temperature is greater than the first temperature.

In still another implementation, the method further includes baking the cured planarization layer to form a baked planarization layer. Exposing the photocurable composition to the first actinic radiation is performed for a first radiation dose, and exposing the photocurable composition to the second actinic radiation is performed for a second radiation dose. A thermal shrinkage of the baked planarization layer is less than a thermal shrinkage of a different baked planarization layer formed from the photocurable composition by exposing the photocurable composition to a single radiation dose at the ambient temperature, followed by the baking at a baking temperature and a soak time, wherein the single radiation dose is a sum of the first radiation dose and the second radiation dose.

In a particular implementation, baking the cured planarization layer is performed at a baking temperature in a range from 300° C. to 500° C. and a soak time in a range from 1 minute to 60 minutes.

In yet another implementation, the photocurable composition includes a polymerizable material that includes an aryl group.

In a particular implementation, the polymerizable material includes a vinyl benzene.

In a further implementation, exposing the photocurable composition to the second actinic radiation is performed in an ambient that includes at most 2 mol % of an oxygen-containing gas.

In another implementation, exposing the photocurable composition to the first actinic radiation is performed at a first radiation dose, exposing the photocurable composition to the second actinic radiation is performed at a second radiation dose, and the first radiation dose is at most 30% of a sum of the first radiation dose and the second radiation dose.

In another aspect, a method can include exposing a photocurable composition to a first actinic radiation, wherein the photocurable composition is positioned between a substrate and a superstrate; removing the superstrate from the photocurable composition; and exposing the photocurable composition to a second actinic radiation to form a cured planarization layer. Removing the superstrate can be performed after exposing the photocurable composition to the first actinic radiation and before exposing the photocurable composition to the second actinic radiation.

In an implantation, the method further includes baking the cured planarization layer to form a baked planarization layer.

In a particular implementation, baking the cured planarization layer is performed at a baking temperature of at least 300° C. and a soak time of at least 1 minute.

In a more particular implementation, baking the cured planarization layer is performed at the baking temperature of at most 500° C. and the soak time of at most 60 minutes.

In another more particular implementation, exposing the photocurable composition to the first actinic radiation is performed for a first radiation dose, and exposing the photocurable composition to the second actinic radiation is performed for a second radiation dose. A thermal shrinkage of the baked planarization layer is less than a thermal shrinkage of a different baked planarization layer formed from the photocurable composition by exposing the photocurable composition to a single radiation dose at an ambient temperature, followed by baking at the baking temperature and the soak time, wherein the single radiation dose is a sum of the first radiation dose and the second radiation dose.

In a further implementation, exposing the photocurable composition to the first actinic radiation is performed at a first temperature, exposing the photocurable composition to the second actinic radiation is performed at a second temperature, and the second temperature is greater than the first temperature.

In a further aspect, a system can include a first radiation exposure station including a first actinic radiation source configured to emit a first actinic radiation at a first wavelength less than 700 nm to expose a photocurable composition that is disposed between a substrate and a superstrate; a superstrate removal tool to remove the superstrate from the photocurable composition; a second radiation exposure station located remotely with respect to the first radiation exposure station. The second radiation exposure station can include a second actinic radiation source configured to emit a second actinic radiation at a second wavelength less than 700 nm to expose the photocurable composition and form a cured planarization layer; and a heating means for heating the photocurable composition and the substrate to a radiation exposure temperature. The system can further include a controller configured to activate the superstrate removal tool to remove the superstrate after a first radiation exposure within the first radiation exposure station and before a second radiation exposure within the second radiation exposure station; and control the heating means to heat the photocurable composition and the substrate to the radiation exposure temperature that is greater than an ambient temperature.

In an implementation, the system further includes a dispense head configured to dispense the photocurable composition over the substrate.

In another implementation, a first unit includes the dispense head, the superstrate removal tool, and the first radiation exposure station, and a second unit includes the second radiation exposure station, wherein the second unit is different and spaced apart from the first unit.

In a further implementation, the system further includes a bake station configured to heat the cured planarization layer to form a baked planarization layer, wherein the bake station is configured to heat the substrate and the cured planarization layer to a baking temperature in a range from 300° C. to 500° C.

### BRIEF DESCRIPTION OF THE DRAWINGS

Implementations are illustrated by way of example and are not limited to the accompanying figures.

FIG. 1 includes an illustration of a cross-sectional view of portions of a substrate, a layer of a photocurable composition, and a superstrate before photocuring the photocurable composition.

FIG. 2 includes an illustration of a cross-sectional view of the substrate and the layer of FIG. 1 after photocuring and baking.

FIG. 3 includes a conceptual view of a portion of a system that can be used in forming a planarization layer from a photocurable composition.

FIG. 4 includes a cross-sectional view of a cure unit within the system of FIG. 3.

FIG. 5 includes a conceptual view of another portion of the system of FIG. 3 including post-exposure bake stations.

FIG. 6 includes a conceptual view of a portion of another system that can be used in forming a photocured planarization layer from a photocurable composition.

FIG. 7 includes a process flow diagram for forming a planarization layer from a photocurable composition.

FIG. 8 includes an illustration of a cross-sectional view of a portion of a substrate chuck and a substrate when dispensing droplets of a photocurable composition over the substrate.

FIG. 9 includes an illustration of a cross-sectional view of the substrate chuck and substrate of FIG. 8 when a superstrate and a combination of the substrate and the droplets are being moved closer to each other.

FIG. 10 includes an illustration of a cross-sectional view of the substrate chuck, substrate, and superstrate of FIG. 9 when forming a layer of the photocurable composition.

FIG. 11 includes an illustration of a cross-sectional view of the substrate chuck, the substrate, the superstrate, and the photocurable layer of FIG. 10 during photocuring of the photocurable layer to form a partly cured planarization layer.

FIG. 12 includes a graph including a plot of evaporation loss after removing the superstrate and heating the partly cured planarization layer at 50° C. for 10 minutes as a function of dose of actinic radiation during a first exposure of the photocurable composition.

FIG. 13 includes an illustration of a cross-sectional view of the substrate chuck, the substrate, and the partly cured planarization layer of FIG. 11 after removing the superstrate.

FIG. 14 includes an illustration of a cross-sectional view of the substrate chuck, the substrate, and the partly cured planarization layer of FIG. 12 during heating of the partly cured planarization layer.

FIG. 15 includes an illustration of a cross-sectional view of the substrate chuck, the substrate, and the partly cured planarization layer of FIG. 14 during photocuring of the partly cured planarization layer to form a photocured planarization layer.

FIG. 16 includes an illustration of a cross-sectional view of the substrate chuck, the substrate, and a photocured planarization layer of FIG. 15 during baking of the photocured planarization layer to form a baked planarization layer.

FIG. 17 includes an illustration of a cross-sectional view of the substrate and the baked planarization layer of FIG. 16 after removing the substrate and the baked planarization layer from the substrate chuck.

FIG. 18 includes a graph including plots of shrinkage as a function of total dose of actinic radiation during both exposures, where shrinkage is between the thickness of the partly cured layer and the baked planarization layer.

Skilled artisans appreciate that elements in the figures are illustrated for simplicity and clarity and have not necessarily been drawn to scale. For example, the dimensions of some of the elements in the figures can be exaggerated relative to other elements to help improve understanding of implementations of the invention.

### DETAILED DESCRIPTION

The following description in combination with the figures is provided to assist in understanding the teachings disclosed herein. The following discussion will focus on specific implementations of the teachings. This focus is provided to assist in describing the teachings and should not be interpreted as a limitation on the scope or applicability of the teachings.

Unless otherwise defined, all technical and scientific terms used herein have the same meaning as commonly understood by one of ordinary skill in the art to which this invention belongs. The materials, methods, and examples are illustrative only and not intended to be limiting. To the extent not described herein, many details regarding specific materials and processing acts are conventional and can be found in textbooks and other sources within the arts.

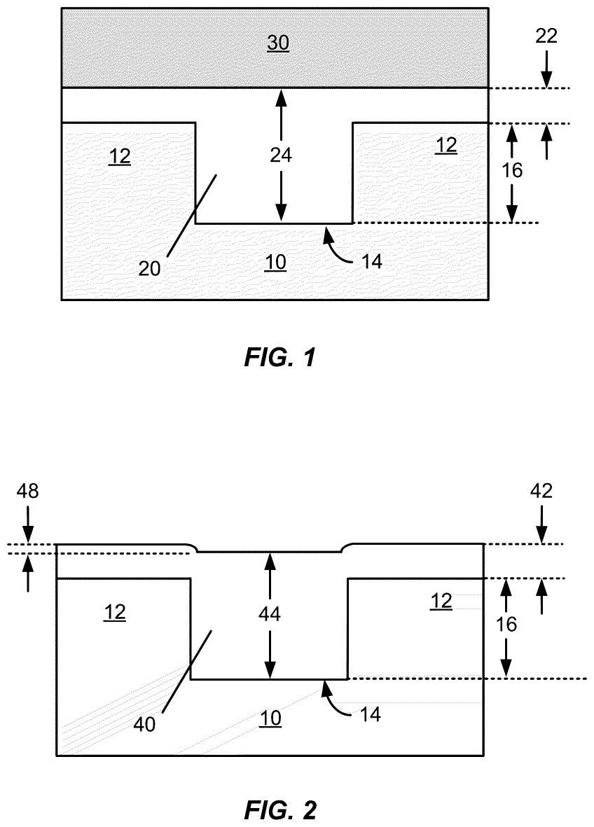

Before addressing details of systems and methods that can be used to achieve benefits as described herein, thickness changes due to processing and planarization performance is addressed and described with respect to FIGS. 1 and 2 that illustrate how the shape of a layer of a photocurable composition can change during processing. The particular thicknesses and depths are provided to illustrate a particular example and not to limit the scope of the present invention as defined in the appended claims.

FIG. 1 includes a cross-sectional view of portions of a substrate 10, a layer 20 of a photocurable composition before photocuring (hereinafter, “pre-cured layer”), and a superstrate 30 having a planar, bottom surface. The substrate 10 includes features 12 and a trench 14 between the features 12. Dimension 16 corresponds to the depth of the trench 14 and is 200 nm for this particular example.

The upper surface of the pre-cured layer 20 of the photocurable composition is planar because the photocurable composition is a fluid that contacts the planar, bottom surface of the superstrate 30. Dimension 22 corresponds to the thickness of the pre-cured layer 20 between features 12 and bottom surface of the superstrate 30. In this particular example, dimension 22 is 40 nm. Dimension 24 corresponds to the thickness of the pre-cured layer 20 between the bottom of the trench 14 and the bottom surface of the superstrate 30. Dimension 24 is a sum of dimension 16 (depth of the trench 14) and dimension 22 (thickness of the pre-cured layer over the features 12). Dimension 24 can be determined using Equation 1 below.

$${D}_{24} = {D}_{16} + {D}_{22} , \qquad ( Equation 1 )$$

where
D₂₄ is dimension 24,
D₁₆ is dimension 16, and
D₂₂ is dimension 22.

When using the previously recited depth for dimension 16 and thickness for dimension 22,

$${D}_{24} = 200 nm + 40 nm = 240 nm .$$

Photocuring the pre-cured layer 20 polymerizes monomers within the photocurable composition and forms a photocured planarization layer. During polymerization, covalent bonds form between monomers within the photocurable composition and pull atoms closer together causing the photocurable composition to shrink. After photocuring, the photocured planarization layer is baked to form a baked planarization layer 40 in FIG. 2. Additional cross-linking occurs during baking and further shrinks the polymerized material. Additionally, some rearrangement and relaxation of the polymer may occur during baking. A reaction may occur, such as oxidation, decomposition, a degradation of the material at high temperature, or a combination thereof. Further, some evaporation may occur during processing and affect the thickness.

The polymerization, any or all of the previously described reactions, and evaporation can contribute to shrinkage. FIG. 2 includes the substrate 10 and the baked planarization layer 40 after the superstrate 30 is removed. In the particular example, the baked planarization layer 40 has shrunk by 5% (a thickness change of −5%) as compared to the pre-cured layer 20. Dimension 42 corresponds to the thickness of the baked planarization layer 40 over the features 12, and dimension 44 corresponds to the thickness of the baked planarization layer 20 within and over the trench 14. Due to the thickness change of −5%, dimension 42 is 95% of dimension 22, and dimension 44 is 95% of dimension 24. Thus, dimension 42 is 38 nm, and dimension 44 is 228 nm.

While the upper surface of the pre-cured layer 16 was at the same elevation, the baked planarization layer 40 has an upper surface with different areas lying at different elevations. Dimension 48 corresponds to the elevational difference along the upper surface of the baked planarization layer 40 between (1) portions of the baked planarization layer 40 overlying the features 12 of the substrate 10, and (2) a portion of the baked planarization layer 40 over the trench 14. Dimension 48 can be determined using Equation 2 below.

$${D}_{48} = {D}_{42} - ( {D}_{44} - {D}_{16} ) , \qquad ( Equation 2 )$$

where
D₄₈ is dimension 48,
D₄₂ is dimension 42, and
D₄₄ is dimension 44.

When using the values for the dimensions,

$${D}_{48} = 38 nm - ( 228 nm - 200 nm ) = 10 nm .$$

Advanced fabrication processes may require that the thickness change be no more than 8 nm regardless of the depth of the trench 14. Thus, the 10 nm thickness change corresponding to the substrate 10 and baked planarization layer 40 in FIG. 2 may cause problems during subsequent processing when making an electronic device. The thickness change would need to be no more than-4% to achieve 8 nm for the dimension 48.

In this specification, a thickness change can be between any two of (1) a pre-cured layer of a photocurable composition, (2) a partly cured planarization layer corresponding to the pre-cured layer, (3) a photocured planarization layer corresponding to the partly cured planarization layer, or (4) a baked planarization layer corresponding to the photocured planarization layer. Unless explicitly stated to the contrary, the thickness change is expressed as a percentage.

A thickness change can be determined using Equation 3 below:

$$( ( {T}_{{2}^{-}} {T}_{1} ) / {T}_{1} ) * 100 \% , \qquad ( Equation 3 )$$

where
T₁ is the thickness of a layer at a relatively earlier point in the process, and
T₂ is the thickness of the layer at a relatively later point in the process.

For example, T₁ can be the thickness of the pre-cured layer, and T₂ can be the thickness of the photocured planarization layer or the thickness of the baked planarization layer. Alternatively, T₁ can be the thickness of the partly cured planarization layer, and T₂ can be the thickness of the baked planarization layer. A negative value corresponds to shrinkage, and a positive value corresponds to expansion. A thickness change is described in terms of how far the thickness change is from 0%. Thus, a thickness change of −4.0% may be decreased to −1.0%, although, literally, −4.0% is less than −1.0%.

Thickness measurements for determining thickness change should be at substantially the same location and surface feature, such as over a protrusion, within a recession, within a scribe lane between dies, or the like and the same thickness measurement tool. The thickness measurements should be within an area of the substrate surrounded by an exclusion zone extending for a distance in a range from 1 mm to 9 mm from the peripheral edge toward the center of the substrate, for example 3 mm. The thickness measurements may be made using an Atomic Force Microscope (AFM); an interferometer; an ellipsometer; a profilometer; or any suitable instrument for measuring a thickness of a layer or a surface profile of a layer. As an alternative to a thickness measurement, a relative height difference at two locations may be measured as this may be representative of the planarity of the planarization layer. In an implementation, a contour map may be generated from the upper surface of a layer to illustrate elevational changes across such surface.

The thickness change can be a single thickness change or an average of a plurality of thickness changes between pairs of thickness measurements or an average from a contour map corresponding to the upper surface of a pre-cured layer, a partly cured planarization layer, a photocured planarization layer, or a baked planarization layer.

A method can include exposing a photocurable composition to a first actinic radiation at a first temperature; and exposing the photocurable composition to a second actinic radiation at a second temperature to form a cured planarization layer. The second temperature can be greater than an ambient temperature and different from the first temperature.

The method can be performed by a system. The system can include a first radiation exposure station including a first actinic radiation source, a superstrate removal tool, a second radiation exposure station located remotely with respect to the first radiation exposure station, and a controller. The first actinic radiation source can emit a first actinic radiation at a first wavelength less than 700 nm to expose a photocurable composition that is disposed between a substrate and a superstrate. The superstrate removal tool can remove the superstrate from the photocurable composition. The second radiation exposure station can include a second actinic radiation source and a heating means. The second actinic radiation source can emit a second actinic radiation at a second wavelength less than 700 nm to expose the photocurable composition and form a photocured planarization layer. The heating means can heat the photocurable composition and the substrate to a radiation exposure temperature. The controller can be configured to activate the superstrate removal tool to remove the superstrate after a first radiation exposure within the first radiation exposure station and before a second radiation exposure within the second radiation exposure station. The controller can be further configured to control the heating means to heat the photocurable composition and the substrate to the radiation exposure temperature that is greater than an ambient temperature.

The method and system can help to achieve a high manufacturing volume and keep a thickness change between a pre-cured layer of a photocurable composition or a partly cured planarization layer and its corresponding baked planarization layer from being too large. In an implementation, a substrate and a pre-cured layer can be exposed to the first actinic radiation source for a relatively short time in the first radiation exposure station to form a partly cured planarization layer. The relatively short time helps to achieve the high manufacturing volume. The partly cured planarization layer can be heated and exposed to the second actinic radiation source in a second radiation exposure station for a relatively longer time to help the thickness change be an acceptable value.

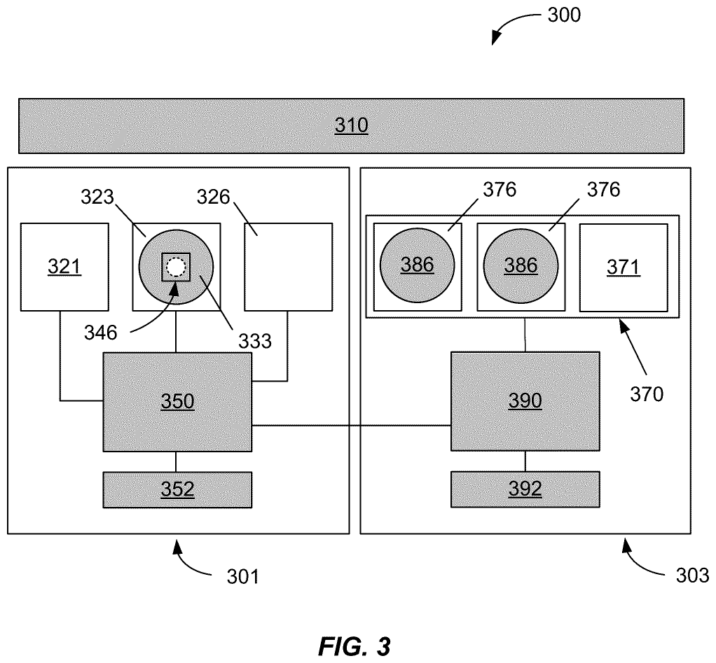

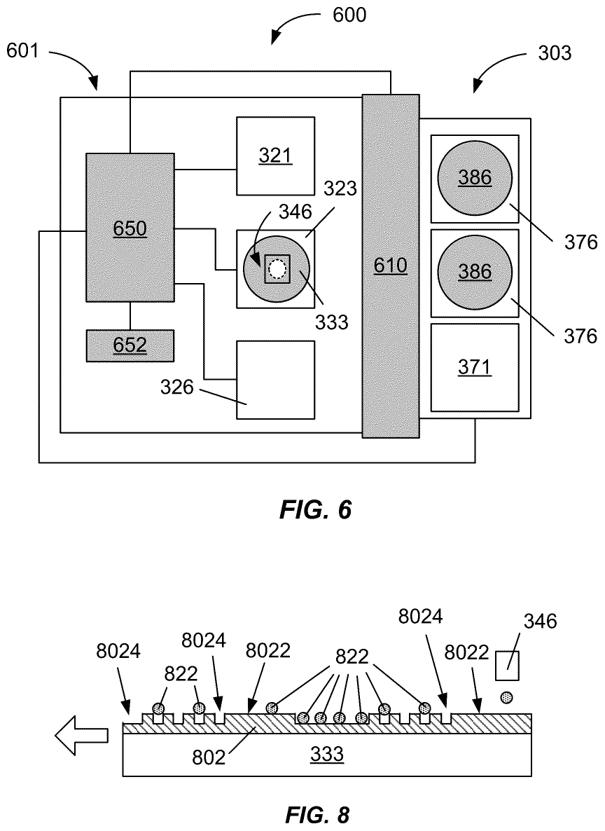

The method can be performed within a system 300 in FIG. 3 to 5 or a system 600 in FIG. 6. The system 300, the system 600, or both systems can further include a post-exposure bake apparatus 500 in FIG. 5 that can perform a baking operation. The systems are well suited for an IAP process.

After reading this specification, skilled artisans will be able to determine the number of apparatuses and their corresponding operations when designing a system. In the description below, the system 300 in FIGS. 3 to 5 will be addressed before addressing the system 600 in FIG. 6.

FIGS. 3 to 5 includes a conceptual diagram of a system 300 that can be used to form a baked planarization layer from a photocurable composition overlying a substrate. The system 300 can include a curing unit 301 that can be used to convert the photocurable composition into a partly cured planarization layer, another curing unit 303 that can be used to convert the partly cured planarization layer into a photocured planarization layer, and the post-exposure bake apparatus 500 that can be used to bake the photocured planarization layer into a baked planarization layer. The units 301 and 303 may be parts of the same apparatus or different apparatuses The photocurable composition will be mostly cured before baking. Some curing may occur during the post-exposure baking operation.

The cure unit 301 includes a substrate pod 321, a dispense station 323, a radiation exposure station 326, a controller 350, and a memory 352. The dispense station 323 can include a substrate chuck 333 that can be coupled to a stage (not illustrated) that allows the substrate chuck 333 to move between the stations 323 and 326. The cure unit 303 includes a cure unit 370, a controller 390, and a memory 392. The cure unit 370 can include a substrate pod 371 and radiation exposure stations 376 that include substrate chucks 386. The bake apparatus 500 can include a substrate transfer tool 510, a bake unit 570, a controller 550 and a memory 552. The bake unit 570 can include a substrate pod 571 and one or more bake stations 576 that each include a substrate chuck 586.

Many of previously-mentioned components are described below with respect to the functions that each performs. More details regarding operation of the components, and particularly the stations 323, 326, 376 and 576, are described in more detail later in this specification with respect to methods of using the system 300.

The substrate transfer tool 310 can be configured to transfer one or more substrates to or from any of the substrate pod 321, the dispense station 323, the radiation exposure station 326, the radiation exposure stations 376, and the substrate pod 371. The substrate transfer tool 510 can be configured to transfer one or more substrates to or from any of the substrate pod 571 and the bake stations 576. The substrate transfer tools 310 and 510 may be or include one or more components of an Equipment Front End Module (EFEM). The components of the EFEM can include one or more of each of the following: a robot arm, a robot hand adapted for holding substrates, a sensor, a motor for moving the robot arm, another motor for moving the robot arm, and the like. The robot arm can be configured to move the substrate with a layer between stations, for example, from the dispense station 323 to the radiation exposure station 326. In an implementation, a particular substrate and a superstrate may have similar shapes and sizes. The substrate transfer tool 310 can be identical to or different from the substrate transfer tool 510.

Referring to FIGS. 3 to 5, the substrate pods 321, 371, and 571 can hold a plurality of substrates. A substrate can be removed from the substrate pod 321, processed at stations of the system 300, such as the stations 323, 326, 376, or a combination thereof, and moved to the substrate pod 371 or another substrate pod when processing in the portion of the system 300 illustrated in FIG. 3 is completed. A substrate can be removed from the substrate pod 571, processed at one or more of the bake stations 576, and returned to the substrate pod 571 or another substrate pod when baking is completed.

The dispense station 323 can be configured to receive a substrate and dispense a photocurable composition over the substrate. When the substrate is over the substrate chuck 333, the dispense head 346 can be used to dispense a photocurable composition over the substrate. The dispense head 346 can include one or more nozzles that dispense the photocurable composition. The dashed line within the dispense head 346 is used to indicate that the photocurable composition is dispensed along the bottom side of the dispense head 346. A stage coupled to the substrate chuck 333, the dispense head 346, or both can be configured to move when dispensing the photocurable composition. More details regarding the photocurable composition and methods of dispensing and processing the photocurable composition are described later in this specification. The stage coupled to the substrate chuck 333 can transfer the substrate and the photocurable composition overlying the substrate from the dispense station 323 to the radiation exposure station 326.

If a superstrate is not yet in contact with the photocurable composition, the superstrate can be placed in contact with droplets of the photocurable composition causing droplets of the photocurable composition to coalesce and form a pre-cured layer of the photocurable composition. The superstrate can be placed in contact with the droplets when the substrate is within the radiation exposure station 326 or within the dispense station 323.

The radiation exposure station 326 can be configured to partly cure the photocurable composition. A pre-cured layer of the photocurable composition can be exposed to actinic radiation when the pre-cured layer is at room temperature. Ambient temperature is the temperature of the room in which a station that performs photocuring within an apparatus is located. Thus, the ambient temperature can be the room temperature. For example, the ambient temperature may be in a range from 20° C. to 25° C. The actinic radiation can cause a polymerizable material within the photocurable composition to polymerize and form the partly cured planarization layer. A partly cured planarization layer refers to the layer of the polymerized photocurable composition after the photocurable layer is photocured sufficiently to allow the superstrate to be removed but is insufficiently cured for baking. The superstrate can be removed when the radiation exposure operation in the radiation exposure station 326 is completed. The photocurable composition can include an internal mold release agent that remains in the partly cured planarization layer after polymerization. The internal mold release agent can help to reduce the likelihood of damaging or removing part or all of the partly cured planarization layer when removing the superstrate. The substrate transfer tool 310 can transfer the substrate and the partly cured planarization layer from the radiation exposure station 326 to one of the heated radiation exposure stations 376.

The heated radiation exposure stations 376 can be configured to perform two operations. The heated radiation exposure station 376 can be configured to heat the partly cured planarization layer and expose the partly cured planarization layer to actinic radiation to further cure the partly cured planarization layer to form a photocured planarization layer. Heating the substrate and partly cured planarization layer can be performed before or before and during exposure to actinic radiation within the station 376 to form the photocured planarization layer. In another implementation, the heating and exposing to actinic radiation can be performed in two different stations when the heating is completed before the exposing to actinic radiation. Sufficient thermal shielding may be used to help keep heat from the heated radiation exposure stations 376 from adversely affecting operation of another portion of the system 300, such as the cure unit 301.

Heating means associated with the heated radiation exposure stations 376 can be activated to heat the photocurable composition. More details regarding the heating means for the heated radiation exposure stations 376 are described later in this specification. A direct temperature measurement of the partly cured planarization layer may be difficult to obtain. Thus, the temperature of the partly cured planarization layer can correspond to a different temperature within the heated radiation exposure station 376. The temperature of the partly cured planarization layer may be correlated to the temperature of its corresponding substrate chuck 386, the substrate overlying such substrate chuck 386, or if present, a superstrate in contact with the partly cured planarization layer. A user of the system 300 may control operations using the temperature of the substrate chucks 386, the substrate, or, if present, the superstrate because a direct temperature measurement of the partly cured planarization layer may not be practical.

When the temperature of the substrate chuck 386, the substrate, or the superstrate is at a targeted temperature or within a tolerance of such temperature, the heating means can be deactivated or be put in a holding state to keep the substrate chuck 386 or the substrate at the targeted radiation exposure temperature or within a tolerance of such temperature. The tolerance of such temperature can be +/−5° C., 2° C., 1° C., or 0.5° C. of the targeted temperature. The targeted temperature may be the same or different from a desired radiation exposure temperature when exposing the partly cured planarization layer to actinic radiation. The targeted temperature can be determined after a desired radiation exposure temperature is known. More details regarding the targeted temperature are described with respect to methods of using the system 300.

When the partly cured planarization layer is at the radiation exposure temperature, the partly cured planarization layer can be exposed to actinic radiation to form a photocured planarization layer. The actinic radiation can cause a polymerizable material within the photocurable composition to polymerize further. The photocured planarization layer refers to the layer of the polymerized photocurable composition after the partly cured planarization layer of the photocurable composition is photocured using actinic radiation and before the layer of polymerized photocurable composition is further processed during a post-exposure baking operation.

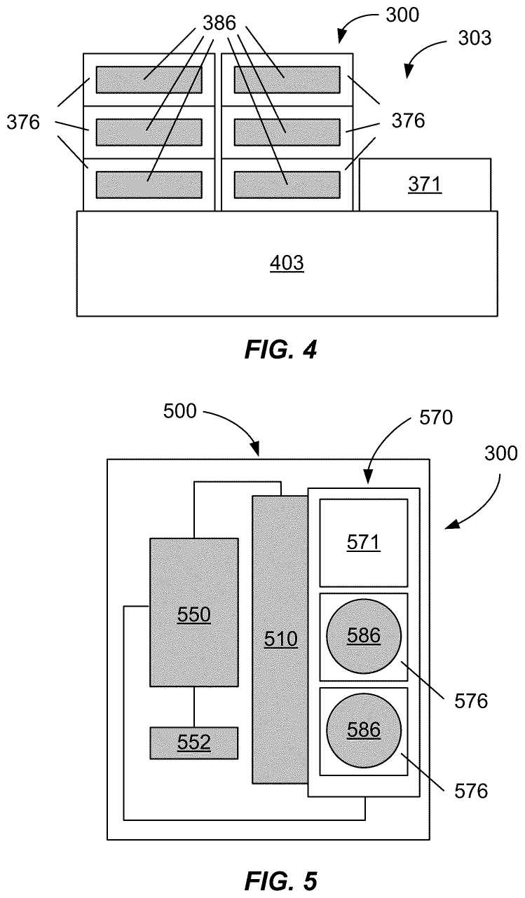

FIGS. 3 and 4 include a top view of the system 300 and a cross-sectional view of the cure stations 376 and the substrate pod 371 that overlie a base housing 403. A controller 390 and a memory 392 (FIG. 3) may be located within the base housing 403 (FIG. 4). The organization of the cure stations 376 can be planar where cure stations 376 lie along a single plane, may be stacked as illustrated in FIG. 4, or a combination of cure stations 376 lying along a single plane and another combination of cure stations 376 being stacked. Stacking the cure stations 376 can help to reduce the area occupied by the cure unit 303. The number of cure stations 376 within a stack can be 2 or more. Due to height constraints within a room where the cure unit 303 is located and the height of each cure stations, the number of cure stations 376 within a stack may be limited to 9 stations, 7 stations, or 5 stations. The number of stacks can be 1 or more. The number of stacks may be limited by available floor space within the room in which the cure unit is located. The number of stacks of cure stations 376 may be limited to 9 stacks, 7 stacks, or 5 stacks. FIG. 4 illustrates 2 stacks to allow for equipment redundancy, should one of the stacks be out of service, without occupying too much area of the room.

Referring to FIG. 5, the post-exposure bake unit 570 can include the substrate pod 571 and post-exposure bake stations 576 that include substrate chucks 586. The post-exposure bake stations 576 can further polymerize or crosslink the photocurable composition within the photocured planarization layer due to thermal curing, cause a different reaction of a component within the photocurable composition, drive out a volatile component within the photocurable composition, or the like. The post-exposure bake stations 576 can have any of the designs, including the heating means, as described with respect to the heated radiation exposure stations 376. The heating means for the post-exposure bake stations 576 can be the same or different from the heat means for the heated radiation exposure stations 376. In an implementation, the post-exposure bake stations 576 can include a heating means configured to operate at a higher temperature as compared to the heated radiation exposure stations 376. The temperature used for post-exposure baking may be at least 300° C. The highest processing temperature associated with the post-exposure bake stations 576 may be as high as 500° C.

The previously described operation performed by any particular station may be moved or combined with another station. For example, the dispensing and exposing to actinic radiation at room temperature can be performed within the same station. In another configuration, operations performed by one station may be performed in separate stations. For example, heating the partly cured planarization layer may be performed in one station, and exposure of the heated partly cured planarization layer to actinic radiation may be performed in a different station.

Each of the substrate chucks 333, 386, and 586 can be a vacuum chuck, a pin-type chuck, a groove-type chuck, an electrostatic chuck, an electromagnetic chuck, or the like. The substrate chucks 333, 386, and 586 may be the same type, for example, vacuum chucks, or may be different types. For example, one of the substrate chucks can be a vacuum chuck, and another one of the substrate chucks can be an electrostatic or electromagnetic chuck. Each of the substrate chucks 333, 386, and 586 may or may not have a heating element, a cooling element, or both that can be used to heat or cool a substrate and a layer, and if present, a superstrate overlying the substrate.

The controller 350 is coupled to the memory 352 and can control the cure unit 301, the controller 390 to the memory 392 and can control the unit 303, and the controller 550 is coupled to the memory 552 and can control the bake apparatus 500. The controller 350 and the memory 352 are described in more detail below. The description of the controller 350 can apply to the controllers 390 and 550 and the description of the memory 352 can apply to the memories 392 and 552 except as noted when addressing specific details of the system 300.

If needed or desired, any combination of the controllers 350, 390, and 550 can communicate with each other. For example, one or both controllers 350 and 550 can be used to confirm that a particular lot of substrates with photocured planarization layers at the substrate pod 571 have completed processing within the unit 303 before the substrates and photocured planarization layers are baked at the post-exposure bake stations 576 in the unit 570.

The controller 350, 390, and 550 can operate using a computer readable program, optionally stored in memory 352. Any or all of the controllers 350, 390, and 550 can include a processor (for example, a central processing unit of a microprocessor or microcontroller), a field-programmable gate array (FPGA), an application specific integrated circuit (ASIC), or the like. The controllers 350, 390, and 550 can be within the system 300. In another implementation (not illustrated) of the system, any one or more of the controllers 350, 390, and 550 can be at least part of a computer external to the system 300, where such computer is bidirectionally coupled to the system 300.

Any or all of the memories 352, 392, and 392 can include a non-transitory computer readable medium that includes instructions to carry out the actions associated with or between operations. Any or all of the memories 352, 392, and 552 can include a set of registers, a cache memory, a flash memory, a hard drive, or the like. Any or all of the memories 352, 392, and 552 can further include data tables that can be accessed by any one or more of the controllers 350, 390, and 550 to assist in determining an operating parameter, for example, a local areal density of the photocurable composition to be dispensed, a targeted temperature, a radiation exposure temperature, a dose of actinic radiation during one or more radiation exposure operations, a total dose of actinic radiation received by a photocurable composition for all radiation exposure operations, a post-exposure baking temperature, or another parameter used in the methods as described below. As used herein, the total dose is a sum of the doses used in exposing a photocurable composition to actinic radiation. In an implementation, the total dose can be the sum of a dose used in forming a partly cured planarization layer and another dose used in forming a more fully photocured planarization layer.

In another implementation, one or more components, such as the stations 323, 326, 376, and 576, of the system 300 can include a local controller that provides some of the functionality that would otherwise be provided by the controller 350, 390, or 550.

More or fewer controllers and more or fewer memories may be used with respect to the system 300. In another implementation, a single controller can perform all of the functions described with respect to the controllers 350, 390, and 550. Thus, one controller, rather than three controllers may be used with the system 300. In a further implementation, the controller 350 may control the cure units 301 and 303, and thus the controller 390 is not required, or the controller 390 may control the cure units 301 and 303, and thus the controller 350 is not required. In another implementation, a single memory, rather than three memories, may be used with the system 300. In a further implementation, the memory 352 may be used with respect to the cure units 301 and 303, and thus the memory 392 is not required, or the memory 392 may be used with respect to the cure units 301 and 303, and thus the memory 352 is not required.

FIG. 6 includes a system 600 that includes the cure units 601 and 303 into a single apparatus, as opposed to different apparatuses in FIG. 3. The system includes a substrate transfer tool 610 that is disposed between the cure unit 601 and the cure unit 303. The substrate transfer tool 610 can perform any of functions as previously described with respect to the substrate transfer tool 310. The substrate transfer tool 610 may allow for sufficient distance between the cure units 601 and 303 to reduce heat that may be transmitted from the cure unit 303 to the cure unit 601, in particular, the radiation exposure station 326, that may operate at room temperature. The system 600 further includes a controller 650 and a memory 652 that performs the functions as previously described with respect to the controllers 350 and 390 and the memories 352 and 652. The system 600 can further include the post-exposure bake apparatus 500 in FIG. 5. The controller 650 and the memory 652 can be any of the types as described with respect to the controllers 350 and 390 and the memories 352 and 392, respectively.

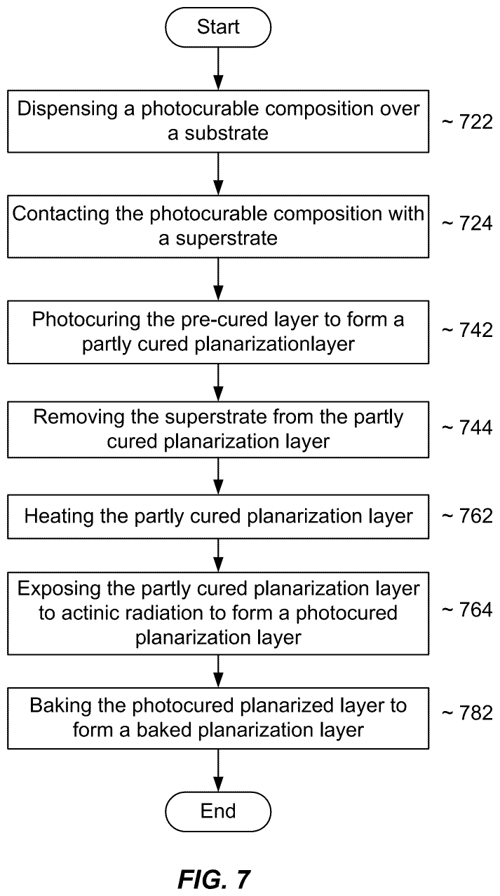

Attention is directed to methods of using the system 300 to form a baked planarization layer over a substrate. FIG. 7 includes a process flow diagram of a method that is described with respect to FIGS. 3 to 5, 8 to 11 and 13 to 17. The process flow diagram also applies to the system 600 in FIG. 6 with respect to the cure units 301 and 303 in FIGS. 3 and 4. A particular process flow is described below in conjunction with the figures and is directed to an IAP process. Many different process flows can be used and still achieve the benefits using the concepts described herein. As used hereinafter, an unpatterned superstrate is referred to as a blank, and a patterned superstrate is referred to as a template. Other variants from the process flow are described later in this specification.

Referring to FIG. 3, the method can include transferring a substrate from the substrate pod 321 to the dispense station 323. The controller 350 or a local controller can transmit a signal for the substrate transfer tool 310 to remove a substrate from the substrate pod 321 and move the substrate to the dispense station 323. The substrate transfer tool 310 can place the substrate on the substrate chuck 333 within the dispense station 323.

The method can include dispensing a photocurable composition over a substrate at block 722 in FIG. 7. The photocurable composition can include a polymerizable material and a photoinitiator. The photocurable composition may or may not include a solvent. In a further implementation, the photocurable composition can contain another additive. A non-limiting example of the other additive can be a surfactant, a dispersant, a stabilizer, an inhibitor, a dye, or a combination thereof.

The polymerizable material can include a single monomer compound or a mixture of monomer compounds. In an embodiment, the polymerizable material can include a multifunctional monomer. The multifunctional monomer in the photocurable composition can make up a majority of the photocurable composition on a weight percent basis. In one embodiment, the amount of the multifunctional monomer in the photocurable composition can be at least 60 wt % based on the total weight of the photocurable composition, or at least 70 wt %, or at least 80 wt %, or at least 90 wt %, or at least 92 wt %, or at least 95 wt % based on the total weight of the photocurable composition. In another implementation, the amount of multifunctional monomer may be at most 99.5 wt % based on the total weight of the photocurable composition, such as at most 99 wt %, or at most 98 wt %, or at most 97 wt %, or at most 95 wt %, or at most 93 wt %, or at most 90 wt % based on the total weight of the photocurable composition. Moreover, the amount of multifunctional monomer can be within a range containing any of the minimum and maximum values noted above, for example, in a range from 60 wt % to 99.5 wt %, 70 wt % to 99 wt %, 80 wt % to 98 wt %, or 90 wt % to 97 wt % based on the total weight of the photocurable composition.

In one implementation, the multifunctional monomer can be a difunctional monomer, a trifunctional monomer, or a tetrafunctional monomer. A functional group can be a vinyl group, an acrylate group, an acrylamide group, a methacrylate group, a maleimide group, an epoxy group, a lactone group, an acetal group, a cyclic ether group, a lactam group, a hydroxyl group, a carboxyl group, a sulfide group, or an amine group, amongst other possibilities. The multifunctional monomer compound can include the same type of functional group (for example, all functional groups within the multifunctional monomer compound are vinyl groups) or different types of functional groups. In an implementation, the multifunctional monomer can include a multifunctional acrylate monomer, a multifunctional vinyl monomer, or a combination thereof.

In a particular implementation, the multifunctional monomer can include at least two acrylate groups or at least three or at least four acrylate groups. As used herein, the term acrylate monomer relates to substituted and non-substituted acrylate monomers. Non-limiting examples of substituted acrylate monomers can be C₁-C₈ alkylacrylate, for example, methacrylate or ethylacrylate.

In another implementation, the multifunctional monomer can include at least two or at least three or at least four vinyl groups.

In an implementation, the multifunctional monomer can include both an acrylate group and a vinyl group. In another implementation, the multifunctional monomer can further include one or more aromatic ring structures.

Another multifunctional monomer can include two or more vinyl groups, and at least one aromatic ring structure, for example, one or more benzene rings. In an implementation, the multifunctional monomer can include a vinyl benzene or divinylbenzene compound. In a particular implementation, the multifunctional monomer can be a biphenyl or diphenylmethane compound including two, three, or four vinyl groups.

Table 1 below includes a list of exemplary multifunctional monomer compounds that can be used as the polymerizable material in the photocurable composition. The list is intended to be illustrative, not comprehensive, and not intended to limit polymerizable material compounds that can be used. Table 1 includes the Chemical Abstracts Service registry number (CAS) when it is applicable.

TABLE 1
Exemplary Multifunctional Monomer Compounds

| Abbreviation/ | | | |
|---|---|---|---|
| Tradename | Chemical Name | CAS | Structure |
| TMPTA | Trimethylolpropane triacrylate | 15625-89-5 | 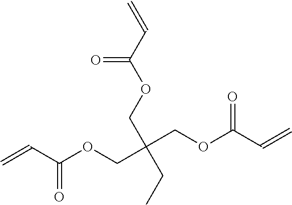 [SMILES: C=CC(=O)OCC(CC)(COC(=O)C=C)COC(=O)C=C] |
| mXDA | 1,3-Phenylenebis(methylene) bisacrylate OR m-xylylene diacrylate | 22757-16-0 | 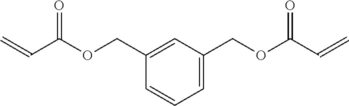 [SMILES: C=CC(=O)OCc1cccc(COC(=O)C=C)c1] |
| VmXDA | 3,5-Bis(methylene) diacrylate styrene | NA | 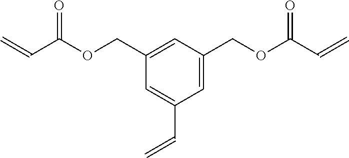 [SMILES: C=CC(=O)OCc1cc(C=C)cc(COC(=O)C=C)c1] |
| DVBA | 3,5-Divinyl benzyl acrylate | NA | 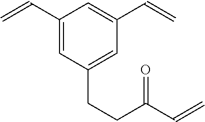 [SMILES: C=CC(=O)CCc1cc(C=C)cc(C=C)c1] |
| DVBPH | 3,3′-Divinyl-1,1′-biphenyl | NA | 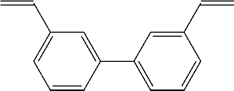 [SMILES: C=Cc1cccc(-c2cccc(C=C)c2)c1] |
| 3VBPH | 3,4′,5-Trivinyl-1,1′-biphenyl | NA | 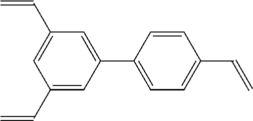 [SMILES: C=Cc1ccc(-c2cc(C=C)cc(C=C)c2)cc1] |
| TVPM | 3,5,3′-Trivinyldiphenylmethane | NA | 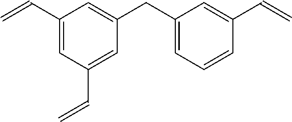 [SMILES: C=Cc1cccc(Cc2cc(C=C)cc(C=C)c2)c1] |
| BVPM | 3,3′-Trivinyldiphenylmethane | NA | 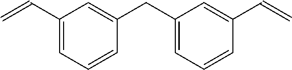 [SMILES: C=Cc1cccc(Cc2cccc(C=C)c2)c1] |
| 4VPM | 3,5,3′,5′- Tetravinyldiphenylmethane | NA | 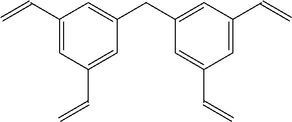 [SMILES: C=Cc1cc(C=C)cc(Cc2cc(C=C)cc(C=C)c2)c1] |
| 4VPH | 3,3′,5,5′-Tetravinyl-1,1′-biphenyl | NA | 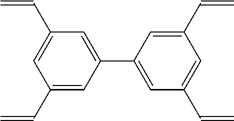 [SMILES: C=Cc1cc(C=C)cc(-c2cc(C=C)cc(C=C)c2)c1] |
| BPADA | bisphenol A diacrylate | 4491-03-06 | 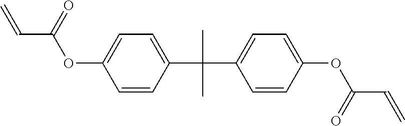 [SMILES: C=CC(=O)Oc1ccc(C(C)(C)c2ccc(OC(=O)C=C)cc2)cc1] |
| BPADMA | bisphenol A dimethacrylate | 3253-39-2 | 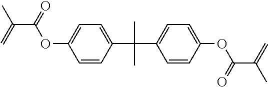 [SMILES: C=C(C)C(=O)Oc1ccc(C(C)(C)c2ccc(OC(=O)C(=C)C)cc2)cc1] |
| DCPDA | Tricyclo[5.2.1.02,6] decanedimethanol diacrylate | 42594-17-2 | 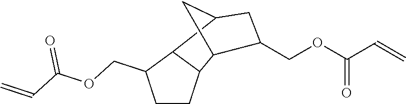 [SMILES: C=CC(=O)OCC1CC2CC1C1CCC(COC(=O)C=C)C21] |
| DVB | 1,3-divinylbenzene | 108-57-6 | 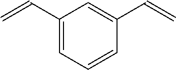 |
| TMTA | tetramethylolmethane tetraacrylate | 4986-89-4 | 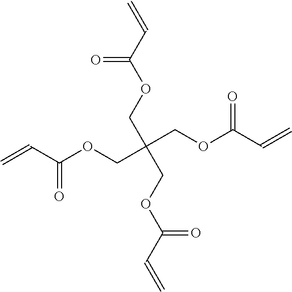 [SMILES: C=CC(=O)OCC(COC(=O)C=C)(COC(=O)C=C)COC(=O)C=C] |

The photoinitiator can include a single photoinitiator compound or a mixture of photoinitiator compounds. In the same or another implementation, a photoinitiator compound can be an oxime ester compound. The oxime ester compound can have a structure of formula (1):

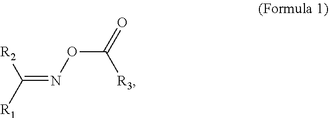

where
R₁ being an aromatic ring system or a heteroaromatic ring system,
R₂ being H or C₁-C₈ alkyl, and
R₃ being H or C₁-C₈ alkyl.

In a particular implementation, the photoinitiator of the photocurable composition can further include a photoinitiator compound that is not an oxime ester compound.

Table 2 below includes a list of exemplary photoinitiator compounds that can be used in the photocurable composition. The list is intended to be illustrative, not comprehensive, and not intended to limit photoinitiator compounds that can be used.

TABLE 2
Exemplary Photoinitiator Compounds

| Abbreviation/ | | | |
|---|---|---|---|
| Tradename | Chemical Name | CAS | Structure |
| Irgacure 819 | Phenylbis(2,4,6- trimethylbenzoyl) phosphine oxide | 162881-26-7 | 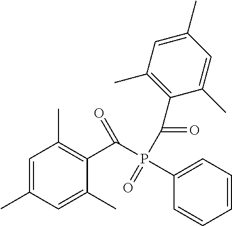 [SMILES: Cc1cc(C)c(C(=O)P(=O)(C(=O)c2c(C)cc(C)cc2C)c2ccccc2)c(C)c1] |
| Irgacure OXE-02 | 1-[{{1-[9-Ethyl-6-(2- methylbenzoyl)-9H- carbazol-3- yl]ethylidene}amino)oxy] ethenone | 478556-66-0 | 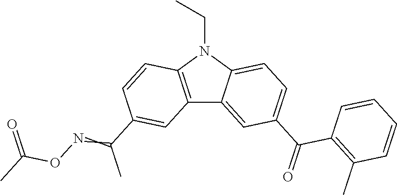 [SMILES: CCn1c2ccc(C(=O)c3ccccc3C)cc2c2cc(C(C)=NOC(C)=O)ccc21] |
| Irgacure OXE-03 | | | 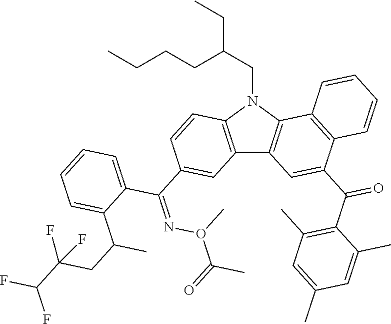 |
| Irgacure OXE-01 | 1-[4-(Phenylthio)phenyl]- 1,2-octanedione 2-(O- benzoyloxime) | 253585-83-0 | 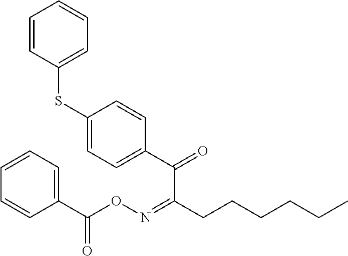 [SMILES: CCCCCC/C(=N/OC(=O)c1ccccc1)C(=O)c1ccc(Sc2ccccc2)cc1] |
| Irgacure 651 | 2,2-Dimethoxy-2- phenylacetophenone | 24650-42-8 | 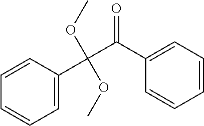 [SMILES: COC(OC)(C(=O)c1ccccc1)c1ccccc1] |
| Omnirad 1316 | | NA | 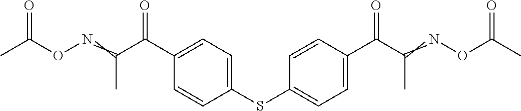 [SMILES: CC(=O)ON=C(C)C(=O)c1ccc(Sc2ccc(C(=O)C(C)=NOC(C)=O)cc2)cc1] |

Irgacure compounds are available from BASF SE of Ludwigshafen am Rhein, Germany. Omnirad is available from IGM Group of Waalwijk Netherlands.

The amount of the photoinitiator in the photocurable composition can be at least 1.0 wt % based on the total weight of the photocurable composition, at least 1.5 wt %, at least 2.0 wt %, at least 2.5 wt %, at least 3.0 wt %, at least 3.5 wt %, or at least 4.0 wt % based on the total weight of the photocurable composition. In another aspect, the amount of the photoinitiator in the photocurable composition may be at most 10.0 wt % based on the total weight of the photocurable composition, at most 8.0 wt %, at most 7.0 wt %, at most 6.0 wt %, at most 5.0 wt %, or at most 4.0 wt % based on the total weight of the photocurable composition. The amount of the photoinitiator in the photocurable composition can be a value between any of the minimum and maximum numbers noted above, for example, in a range from 1.0 wt % to 10.0 wt %, 1.5 wt % to 8.0 wt %, or 2.0 wt % to 7.0 wt % based on the total weight of the photocurable composition.

In an implementation, the photocurable composition can be essentially free of a solvent. As used herein, if not indicated otherwise, the term solvent relates to a compound which can dissolve or disperse the polymerizable material but does not itself polymerize during exposing to actinic radiation of the photocurable composition. The term “essentially free of a solvent” means herein an amount of solvent being at most 5 wt % based on the total weight of the photocurable composition. In a particular implementation, the amount of a solvent can be at most 3 wt %, at most 2 wt %, at most 1 wt % based on the total weight of the photocurable composition, or the photocurable composition can be free of a solvent, except for unavoidable impurities.

In another aspect, the photocurable composition can comprise a solvent in an amount greater than 5 wt % based on the total weight of the photocurable composition. In a particular aspect, the amount of solvent can be at least 10 wt % based on the total weight of the photocurable composition, or at least 15 wt %, at least 20 wt %, or at least 25 wt % based on the total weight of the photocurable composition. In another aspect, the amount of solvent may be at most 40 wt %, at most 30 wt %, at most 20 wt %, or at most 10 wt % based on the total weight of the photocurable composition. In a particular implementation, the amount of the solvent in the photocurable composition can be a value between any of the minimum and maximum numbers noted above, for example, in a range from 5 wt % to 40 wt %, 10 wt % to 30 wt %, or 15 wt % to 20 wt % based on the total weight of the photocurable composition.

The surfactant can include a single surfactant compound or a mixture of surfactants. A surfactant compound can be a fluorine-containing compound, and in an implementation, the surfactant compound can be a fluoro-organic compound. Table 3 below includes a list of exemplary surfactant compounds that can be used in the photocurable composition. The list is intended to be illustrative, is not comprehensive, and not intended to limit surfactant compounds that can be used.

TABLE 3
Exemplary Surfactant Compounds

| Abbreviation/ | | | |
|---|---|---|---|
| Tradename | Chemical Type | CAS | Structure |
| FS2000M1 | Nonionic fluorosurfactant | 1702364-63-3 | NA |
| | (poly(oxyalkylene) based | | |
| | fluorosurfactant) | | |
| Capstone FS- | nonionic fluorosurfactant | NA | NA |
| 3100 | | | |

Capstone™ FS-3100 is available from The Chemours Company of Wilmington, DE, USA.

The surfactant can be at most 5.0 wt % based on the total weight of the photocurable composition. In a particular implementation, the amount of a surfactant can be at most 3.0 wt %, at most 2.0 wt %, or at most 0.9 wt % based on the total weight of the photocurable composition.

The photocurable composition will be subsequently polymerized and form a photocured planarization layer that is subsequently baked at a temperature of at least 300° C. Thus, the components and amounts of the components for the photocurable composition can be selected so that the resulting photocured planarization layer can withstand the baking operation without being substantially adversely affected by the baking operation.

Returning to the method and FIGS. 3 and 8, the dispense head 346 dispenses droplets 822 of the photocurable composition over the exposed surface of the substrate 802 as illustrated in FIG. 8. During a dispensing operation, the substrate chuck 333 can be coupled to a stage that is configured to move the substrate chuck 333 (illustrated by the arrow adjacent to the substrate 802 in FIG. 8) during a dispensing operation. In another implementation, the dispense head 346 moves while the substrate chuck 333 is stationary, and in a further implementation, both substrate chuck 333 and the dispense head 346 move during dispensing. Thus, the substrate 802 can move, and the dispense head 346 may be stationary or also move.

The substrate 802 can have an exposed surface having a projection that lies at a relatively higher elevation as compared to an adjacent recession. In FIG. 8, the exposed surface of the substrate 802 has protrusions 8022 and recessions 8024. The substrate 802 has a local area with a relatively higher areal density of protrusions 8022 as compared to the recessions 8024 and another local area with a relatively higher areal density of recessions 8024 as compared to the protrusions 8022. A lower areal density of the photocurable composition is dispensed where protrusions 8022 occupy a relatively larger fraction of a local area, and a higher areal density of the photocurable composition is dispensed where recessions 8024 occupy a relatively larger fraction of a different local area. In practice, the exposed surface of the substrate 802 is significantly more complex than illustrated in FIG. 8 and is not limited to only two elevations. The exposed surface of the substrate 802 in FIG. 8 is simplified to aid in understanding the concepts described herein.

The controller 350 or a local controller can transmit signals so that the dispense head 346, a stage coupled to the substrate chuck 333 (when the substrate chuck 333 is coupled to the stage), or both move in a desired direction and velocity, and the dispense head 346 dispenses the droplets 822 of the photocurable composition at a desired rate in order to achieve proper local areal densities of the photocurable composition along the exposed surface of the substrate 802.

Referring to FIGS. 3, 8, and 9, a stage coupled to the substrate chuck 333 can transfer the substrate 802 and the droplets 822 of the photocurable composition from the dispense station 323 to the radiation exposure station 326. The controller 350 or a local controller can transmit a signal for the stage to move the substrate chuck 333, the substrate 802, and the droplets 822 of the photocurable composition from the dispense station 323 to the radiation exposure station 326. The radiation exposure station 326 may include a superstrate handler, a planarization head (not illustrated), or both.

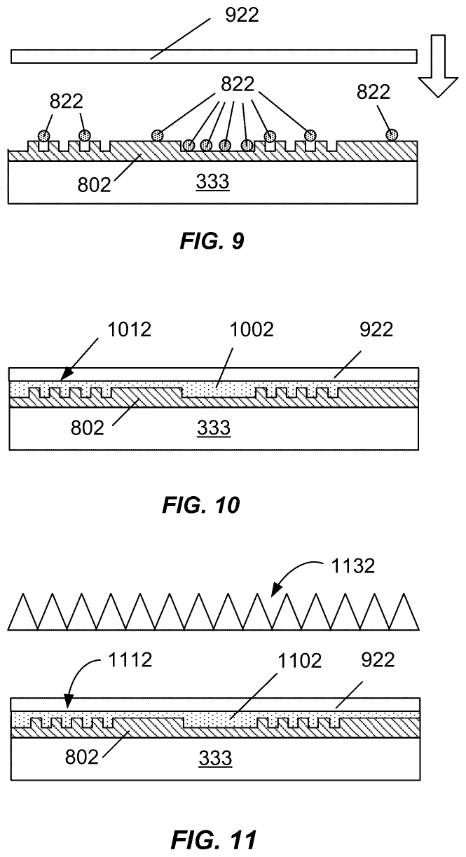

The process further includes contacting the photocurable composition with a superstrate at block 724 in FIG. 7. Referring to FIG. 9, a superstrate 922 can be used to aid in forming a pre-cured layer from the droplets 822 of the photocurable composition. In an implementation, the superstrate 922 can be a blank with a planar bottom surface facing the substrate 802 and the droplets 822. The cure unit 301 can include a superstrate handler (not illustrated) that can be used to move and position the superstrate 922. In the same or different implementation, the superstrate 922 can be held by a planarization head within the radiation exposure station 326.

The superstrate 922 has a transmittance of at least 70%, at least 80%, at least 85%, or at least 90% for actinic radiation used to photocure the photocurable composition. The superstrate 922 can include a glass-based material, silicon, an organic polymer, a siloxane polymer, a fluorocarbon polymer, a sapphire, a spinel, another similar material, or any combination thereof. The glass-based material can include soda lime glass, borosilicate glass, alkali-barium silicate glass, aluminosilicate glass, quartz, fused-silica, or the like. In an implementation, the actinic radiation can be ultraviolet radiation, and a glass-based material can be used for the superstrate 922. The superstrate 922 can have a thickness in a range from 30 microns to 2000 microns. The contacting surface of the superstrate 922 can have a surface area that is at least 90%, 95%, 96%, 97%, or 99% of the area of the substrate 802 and may have surface area that is the same or larger than the substrate 802.

The contacting surface of the superstrate 922 has a two-dimensional shape including a circle, an ellipse, a rectangle (including a square), a hexagon, or the like. The two-dimensional shape can be the same as an outer shape of the substrate 802. For example, both can be circles. In the implementation illustrated in FIG. 9, the contacting surface does not have any recessions and protrusions.

Referring to FIGS. 3, 9, and 10, the controller 350 or a local controller can transmit a signal for the superstrate 922 and the droplets 822 to move closer and contact each other. The superstrate 922 may be moved, the substrate chuck 333 may be moved, or both the superstrate 922 and the substrate chuck 333 can be moved. As the superstrate 922 contacts droplets 822 of the photocurable composition, and the droplets 822 can coalesce to form a pre-cured layer 1002 of the photocurable composition. The upper surface 1012 of the pre-cured layer 1002 conforms to the bottom, contacting surface of the superstrate 922.

The method can include exposing the photocurable composition to actinic radiation at a relatively lower temperature to form a partly cured planarization layer at block 742 in FIG. 7. In an implementation, the relatively lower temperature can be room temperature. Referring to FIG. 3, for a particular photocurable composition, the memory 352 can include information regarding a targeted wavelength or a targeted range of wavelengths for the actinic radiation, a targeted dose or a targeted range of doses to be used for the photocurable composition, or other data related to exposing the photocurable composition to actinic radiation. Such information can be used by the controller 350 or a local controller to determine parameters for exposing the photocurable composition to the actinic radiation. The controller 350 can access the empirical data that may have been previously collected using other substrates. The controller 350 can provide the desired radiation exposure temperature for a particular photocurable composition, the baking temperature that will be used during a post-exposure bake, a dose of actinic radiation that will be used to photocure the pre-cured layer 1002, or a combination thereof. The temperature at the time of exposing to actinic radiation is referred to herein as the actual radiation exposure temperature. The actual radiation exposure temperature can be at or near the desired radiation exposure temperature. The actual radiation exposure temperature can be any of the targeted temperatures and tolerances previously described.

Referring to FIGS. 3, 10, and 11, the controller 350 or a local controller can receive a signal from a temperature sensor or a derivative of such signal and determine if the temperature is at or within a tolerance (for example, +/−5° C., +/−2° C., +/−1° C., or +/−0.5° C.) of the desired radiation exposure temperature. The pre-cured layer 1002 is exposed to actinic radiation when the pre-cured layer 1002 is at room temperature. When the temperature is at or within a tolerance of the desired radiation exposure temperature, the controller 350 or a local controller can transmit a signal for an actinic radiation source 1132 to be activated as illustrated in FIG. 11. Each triangle symbol within the actinic radiation source 1132 can represent an individual radiation source, such as a UV lamp.

Actinic radiation is emitted from the actinic radiation source 1132. At least 70% of the actinic radiation reaching the superstrate 922 is transmitted through the superstrate 922. The actinic radiation transmitted through the superstrate 922 activates the photoinitiator within photocurable composition in the pre-cured layer 1002 to aid in polymerization of the polymerizable material within the photocurable composition. The actinic radiation can have a wavelength of at least 10 nm and less than 700 nm. The actinic radiation can be ultraviolet radiation having a wavelength in a range from 100 nm to 400 nm, and more particularly, in a range from 200 nm to 400 nm. A supplier of the photocurable composition may provide a targeted wavelength or a targeted range of wavelengths to be used to photocure the photocurable composition.

Energy from the exposure to actinic radiation forms a partly cured planarization layer 1102 (FIG. 11) from the pre-cured layer 1002 (FIG. 10). The partly cured planarization layer 1102 has an upper surface 1112. The energy polymerizes the polymerizable material to form a polymer material. The polymer material can be a single polymer compound or may be a co-polymer. The partly cured planarization layer 1102 can be further polymerized during a subsequent heated radiation exposure operation.

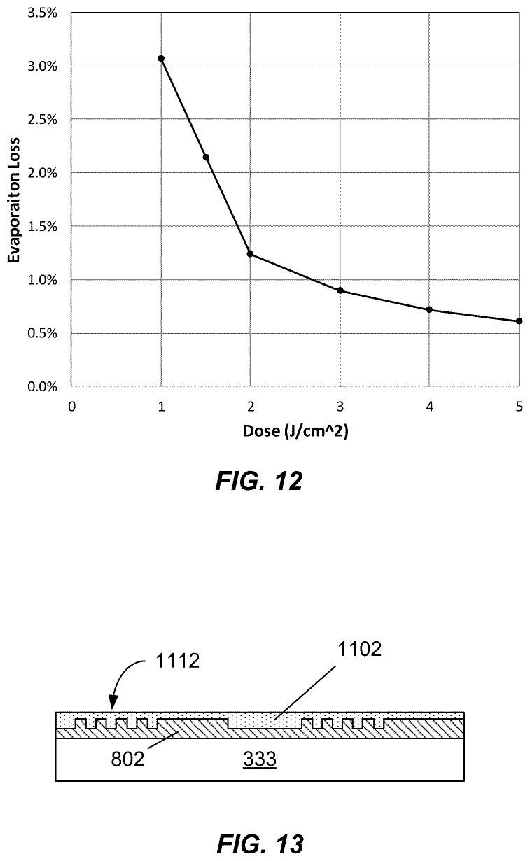

In an implementation, the superstrate 922 can be removed, and evaporation loss from the partly cured planarization layer 1102 may be significant during a subsequent heated radiation exposure operation. At a low dose for the first exposure, an unreacted monomer can remain, at least some of which can evaporate away during a subsequent heated exposure. When a higher dose for the first exposure is used, most of the monomer becomes at least partially polymerized and is not as easily evaporated during a subsequent heated exposure. However, a high dose can take a long time to complete and reduce overall throughput. As such, there is a trade-off between the first exposure time and evaporation loss. Reducing evaporation loss is important because it impacts planarization performance. To demonstrate how dose affects evaporation loss, partly cured planarization layers were prepared with different first exposure doses. After the superstrate was removed, a sample of each was baked on a hotplate at 50° C. for 10 minutes. FIG. 12 includes a plot of evaporation loss as a function of dose used to form the partly cured planarization layer 1102. Evaporation loss is defined as the relative thickness change of a partly cured planarization layer before and after heating at 50° C. for 10 minutes. As the dose for the partly cured planarization layer 1102 is increased, the amount of evaporation loss decreases. However, a larger dose adversely affects the throughput of the cure unit 301.

The dose when forming the partly cured planarization layer 1102 may be affected by whether or not the superstrate 922 is removed before subsequent processing. If the partly cured planarization layer 1102 is insufficiently cured, the partly cured planarization layer 1102 may become distorted or otherwise damaged when removing the superstrate 922. In an implementation, at a dose of less than 1 J/cm², the partly cured planarization layer 1102 may be insufficiently cured to allow for a repeatable removal process to be used in production.

Referring to FIG. 12, at a dose of 3 J/cm², evaporation loss is less than 1%, and the superstrate 922 can be removed from the partly cured planarization layer 1102 without significant damage to the partly cured planarization layer 1102. However, the time needed to achieve the dose may be too long for a high volume manufacturing process. At a dose of 2 J/cm², the evaporation loss is approximately 1.2%, and the superstrate 922 can be removed from the partly cured planarization layer 1102 without significant damage to the partly cured planarization layer 1102. The time needed to achieve the dose may still be unacceptably long. A dose of 1.5 J/cm² may have an acceptable processing time. If a higher evaporation loss can be tolerated and the superstrate removal process is sufficiently reproduceable, the dose of 1.5 J/cm² can be used.

In another implementation, the superstrate 922 may not be removed until after performing a heated radiation exposure to form a photocured planarization layer. In this implementation, evaporation loss can be substantially reduced and damage related to removing the superstrate 922 from an insufficiently cured layer may be obviated. A relatively low dose that would otherwise be unacceptable for evaporation loss, damage to the partly cured planarization layer 1102, or both if substrate removal was performed before further exposing to actinic radiation may be used when the superstrate 922 is not removed until further photocuring is performed.

After reading this specification in its entirety, skilled artisans will be able to determine a dose when forming the partly cured planarization layer 1102 to meet the needs and desires for a particular application.

The method can include removing the superstrate from the partly cured planarization layer at block 744 in FIG. 7. FIG. 13 includes a cross-sectional view of the substrate chuck 333, the substrate 802 and the partly cured planarization layer 1102 at this point in the process.

Referring to FIGS. 3 and 4, the substrate transfer tool 310 can move the substrate 802 and the partly cured planarization layer 1102 from the radiation exposure station 326 within the cure unit 301 to one of the heated radiation exposure stations 376 in the cure unit 303. The substrate chuck 386 within the radiation exposure station 376 is coupled to the substrate 802.

The process further includes heating the partly cured planarization layer at block 762 in FIG. 7 and exposing the partly cured planarization layer to actinic radiation to form a photocured planarization layer at block 764. After the partly cured planarization layer 1102 is heated to a targeted temperature in block 762, the partly cured planarization layer 1102 can be exposed to actinic radiation in block 764. Heating may be terminated before the partly cured planarization layer 1102 is exposed to actinic radiation or heating may be continued to keep the partly cured planarization layer 1102 at the targeted temperature during exposure to actinic radiation.

The targeted temperature for the heating may depend on the desired radiation exposure temperature when the partly cured planarization layer 1102 is exposed to actinic radiation. The desired radiation exposure temperature may depend on the thickness change between the pre-cured layer 1002 and its corresponding baked planarization layer after exposing to actinic radiation and baking or between the partly cured planarization layer 1102 or a photocured planarization layer and its corresponding baked planarization layer.

The elevated radiation exposure temperature may allow a thickness change of 0% or closer to 0% between the pre-cured layer 1002 and its corresponding baked planarization layer or between the partly cured planarization layer 1102 or the photocured planarization layer and its corresponding baked planarization layer. The desired radiation exposure temperature can depend on materials within the photocurable composition. Of the materials within the photocurable composition, the polymerizable material has the largest impact on the temperature selected. The photoinitiator, which can include a single photoinitiator compound or a mixture of photoinitiator compounds, can have a smaller impact on the desired radiation exposure temperature. Other materials within the photocurable composition may have no impact or an insignificant impact on the desired radiation exposure temperature.

Empirical data can be generated to determine a desired radiation exposure temperature. After exposing to actinic radiation and baking, the thickness of the baked planarization layer may be thicker, thinner, or approximately the same as the thickness of the pre-cured layer 1002 or the partly cured planarization layer 1102. Graphs may be generated from the empirical data to determine the thickness change. Significant variables for the graphs can include (1) the particular photocurable composition, (2) the post-exposure baking temperature, (3) the temperature during the exposure to actinic radiation, and (4) dose information, such as the dose of actinic radiation when polymerizing the pre-cured layer 1002 to form the partly cured planarization layer 1102, the dose of actinic radiation when further polymerizing the partly cured planarization layer 1102 to form the photocured planarization layer, the total dose of actinic radiation that the photocurable composition receives for all exposures to actinic radiation to form the photocured planarization layer, or any combination thereof.

Data for thickness changes and the four variables may be stored in a table within the memory 352. For each line within a graph, three of the four variables can be held constant while the last of the three or four variables is varied to determine its impact on the thickness change. For example, for a particular photocurable composition, baking temperature, and total dose are held constant as the radiation exposure temperature is varied. In an implementation where the superstrate 922 remains in contact with the partly cured planarization layer 1102, empirical data collected or simulation data can be generated when the superstrate 922 is present during heating and exposing to actinic radiation. More details regarding the empirical data can be found in the Examples section later in this specification. The description below is directed to a method where the superstrate 922 is removed before heating.

The thickness change between the pre-cured layer 1002 or the partly cured planarization layer 1102 and its corresponding baked planarization layer can be within a tolerance range of a targeted thickness change. A targeted thickness change can be 0%, and the tolerance range may be within a range of values that provide good planarization performance. The tolerance range can be +/−2.0%, +/−1.0%, or +/−0.5%. For example, a production specification may have a thickness change that is 0%+/−1.0%, and thus, the thickness range can be in a range from −1.0% to 1.0%.

The empirical data can be stored within a table in the memory 352 or a database external to the system 300. The controller 350 can receive information regarding the photocurable composition, the dose information, the baking temperature, or a combination thereof that will be used in forming the baked planarization layer and determine a desired radiation exposure temperature that is to be used.

After the desired radiation exposure temperature is determined, a targeted temperature during the heating can be determined by the controller 350 or a local controller. The targeted temperature can be the same as or different from the desired radiation exposure temperature. For example, the substrate 802 and the partly cured planarization layer 1102 may or may not cool between heating and exposing the partly cured planarization layer 1102 to actinic radiation. In an implementation, exposing the partly cured planarization layer 1102 to actinic radiation can be performed while a heating means is maintaining the targeted temperature at or within an allowable tolerance of the desired radiation exposure temperature (for example +/−2.0° C., +/1.0° C., or +/−0.5° C.). In another implementation, the heating means may be deactivated before exposing the partly cured planarization layer 1102 to actinic radiation begins. The targeted temperature may be higher than the desired radiation exposure temperature, so that the partly cured planarization layer 1102 cools to the desired radiation exposure temperature. After reading this specification, skilled artisans will be able to determine a targeted temperature for a potential temperature change between heating and exposing the partly cured planarization layer 1102 to actinic radiation.

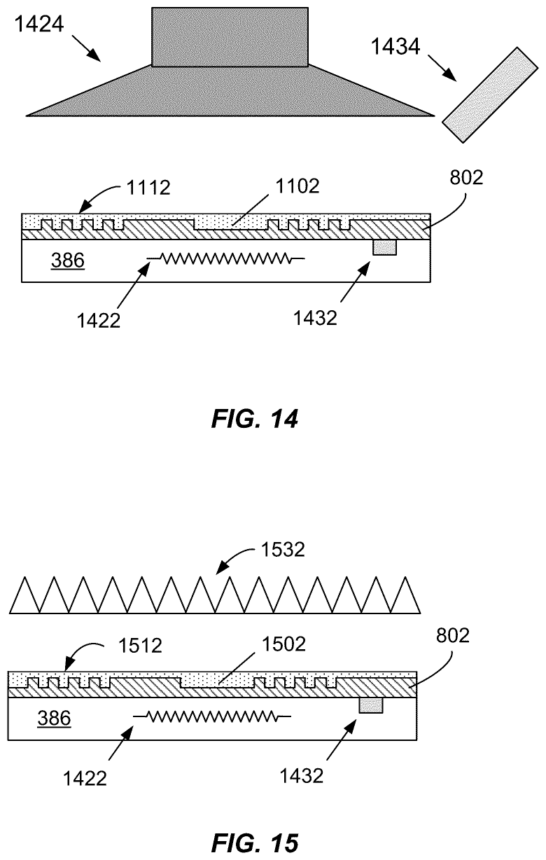

A heating means is used to heat the substrate 802 and the partly cured planarization layer 1102 to the targeted temperature. Referring to FIG. 14, the heating means can include a resistive heating element 1422 within the substrate chuck 333 or a radiative heating element 1424 positioned over the substrate chuck 333. The radiative heating element 1424 can include a heat lamp, an infrared lamp, or the like. Although not illustrated, the heating means can include an induction heater, a microwave generator to generate microwaves, a pump to assist in flowing a heated fluid through a channel within the substrate chuck 333, or a fan to assist in convection by passing a heated gas over the substrate 802 and partly cured planarization layer 1102. The heating means may have only one type of the heating means (for example, resistive heating element, inductive heater, radiative heating element, microwave generator, a pump to flow a heated fluid within the substrate chuck 333, or a fan to assist in convective heating) or a combination of different types of heating means (combination of any two or more of foregoing).

The heating means provides heat so that the substrate 802 and the partly cured planarization layer 1102 reach the targeted temperature that is higher than the ambient temperature. A room in which the system 300 is located can be at an ambient temperature of 20° C. In such a room, heating can raise the temperature of the partly cured planarization layer 1102 so that the partly cured planarization layer 1102 is at 21° C. or higher when exposed to actinic radiation. The room may reach an ambient temperature of 24° C. while the system 300 is operating, and heating can raise the temperature of the partly cured planarization layer 1102 so that the partly cured planarization layer 1102 is at 25° C. or higher when exposed to actinic radiation. Depending on the ambient temperature, the targeted temperature can be at least 21° C., at least 25° C., at least 30° C., at least 35° C., or at least 40° C.

When the partly cured planarization layer 1102 is exposed to a sufficiently high temperature, the photocurable composition can substantially polymerize without being exposed to actinic radiation or cause too much evaporation loss before exposing to actinic radiation is completed. Thus, the targeted temperature should not be so high as to cause substantial polymerization of the photocurable composition or evaporation loss during the heating. In an implementation, the targeted temperature may be at most 120° C. An insignificant amount of polymerization due to thermal curing may or may not occur at 120° C. In another implementation, the targeted temperature of the heating can be at most 95° C., at most 80° C. or at most 70° C. The targeted temperature of the heating can be a value between any of the minimum and maximum numbers noted above, for example, in a range from 25° C. to 120° C., 25° C. to 95° C., 30° C. to 80° C., or 35° C. to 70° C.

Referring to FIG. 14, during heating, the controller 350 or a local controller can receive temperature data from a temperature sensor 1432 or 1434 and transmit a signal that is received by the controller 350 or a local controller so that the controller 350 or the local control can transmit a signal for the heating means, such as the resistive heating element 1422 or the radiative heat element 1424, to heat the substrate 802 and the partly cured planarization layer 1102 to the targeted temperature. After the partly cured planarization layer 1102 reaches the targeted temperature, the heating means can be terminated or may continue to keep the partly cured planarization layer 1102 at the targeted temperature.

Exposure to actinic radiation can be performed to form a photocured planarization layer 1502 in FIG. 15. Referring to FIG. 3, for a particular photocurable composition, the memory 352 can include information regarding a targeted wavelength or a targeted range of wavelengths for the actinic radiation, a targeted total dose or a targeted range of total doses to be used for the photocurable composition, a dose used when exposing the pre-cured layer 1002 to actinic radiation to form the partly cured planarization layer 1102, or other data related to exposing the photocurable composition to actinic radiation. Such information can be used by the controller 350 or a local controller to determine parameters for exposing the partly cured planarization layer 1102 to the actinic radiation. The controller 350 can access the previously described empirical data that can provide the desired radiation exposure temperature for a particular photocurable composition, the baking temperature that will be used during a post-exposure bake, a dose of actinic radiation that will be used to photocure the partly cured planarization layer 1102 to form the photocured planarization layer 1502, a total dose of actinic radiation that will be used for both radiation exposure stations 326 and 376, or a combination thereof. The temperature at the time of the heated radiation exposure is referred to herein as the actual radiation exposure temperature. The actual radiation exposure temperature can be at or near the desired radiation exposure temperature. The actual radiation exposure temperature can be any of the targeted temperatures and tolerances previously described.

Referring to FIGS. 3, 14, and 15, the controller 350 or a local controller can receive a signal from a temperature sensor or a derivative of such signal and determine if the temperature is at or within a tolerance (for example, +/−5° C., +/−2° C., +/−1° C., or +/−0.5° C.) of the desired radiation exposure temperature. When the temperature is at or within a tolerance of the desired radiation exposure temperature, the controller 350 or a local controller can transmit a signal for an actinic radiation source 1532 to be activated as illustrated in FIG. 15. In an implementation, each triangle illustrated for the actinic radiation source 1532 can be a UV lamp.

Actinic radiation is emitted from the actinic radiation source 1532. In an implementation where the superstrate 922 was not previously removed and is still present over the partly cured planarization layer 1102 during the heated radiation exposure, at least 70% of the actinic radiation reaching the superstrate 922 is transmitted through the superstrate 922. The actinic radiation received by the partly cured planarization layer 1102 activates the photoinitiator within photocurable composition in the partly cured planarization layer 1102 to aid in further polymerization of the polymerizable material within the photocurable composition. The actinic radiation can have a wavelength of at least 10 nm and less than 700 nm. The actinic radiation can be ultraviolet radiation having a wavelength in a range from 100 nm to 400 nm, and more particularly, in a range from 200 nm to 400 nm. A supplier of the photocurable composition may provide a targeted wavelength or a targeted range of wavelengths to be used to photocure the photocurable composition.

Energy from the exposure to actinic radiation forms the photocured planarization layer 1502. The photocured planarization layer 1502 has an upper surface 1512. The energy further polymerizes the polymerizable material to form more polymer material or more covalent bonds with neighboring molecules to form a more cross-linked material. The polymer material can be a single polymer compound or may be a co-polymer. The exposure to the actinic radiation during the heated radiation exposure substantially polymerizes but may not fully polymerize the polymerizable material within the partly cured planarization layer 1102. In an implementation, no further exposure to actinic radiation may occur. Further polymerization may occur during a post-exposure baking of the photocured planarization layer 1502 due to thermal curing. A supplier of the photocurable composition may provide a targeted dose or a targeted range of doses to be used for the photocurable composition. Alternatively, skilled artisans may generate empirical data to determine a dose or range of doses that may be used for a particular photocurable composition.

If the superstrate 922 was present when forming the photocured planarization layer 1502, the superstrate 922 can be removed at this point in the method. The photocurable composition can include an internal mold release agent that remains in the photocured planarization layer 1502 after polymerization. The internal mold release agent can help to reduce the likelihood of damaging the photocured planarization layer 1502 or removing part or all of the photocured planarization layer 1502 when removing the superstrate 922.

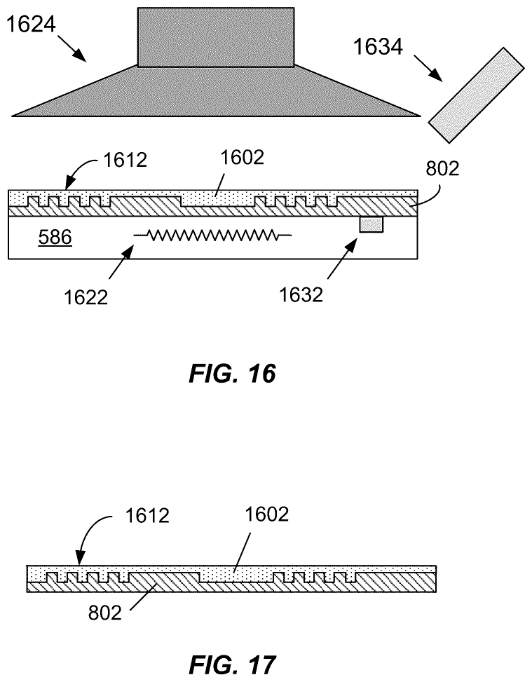

The method can include baking the photocured planarization layer to form a baked planarization layer at block 782 in FIG. 7. During the baking operation, the material within the photocured planarization layer 1502 can further polymerize, cross-link, or both. The baking operation can also help remove a relatively volatile component, if present, from the photocured planarization layer 1502 when forming a baked planarization layer 1602 in FIG. 16. The baked planarization layer 1602 has an upper surface 1612. The baking operation may or may not cause a further thickness change between the photocured planarization layer 1502 and the baked planarization layer 1602.

Referring to FIGS. 3 to 5, 15, and 16, the controller 350 or a local controller can transmit a signal for the substrate transfer tool 310 to remove the substrate 802 and the photocured planarization layer 1502 from the heated radiation exposure station 376 and move the substrate 802 and the photocured planarization layer 1502 to the substrate pod 371. The substrate pod 371 can be moved to the bake apparatus 500 for further processing. In another implementation, the substrate 802 and photocured planarization layer 1502 can be moved to the substrate pod 571 in FIG. 5. The substrate transfer tool 510 can place the substrate 802 on the substrate chuck 586 within one of the post-exposure bake stations 576.

A heating means within the post-exposure bake station 576 is used to heat the photocured planarization layer 1502 (FIG. 15) to form the baked planarization layer 1602 (FIG. 16). Any of the heating means previously described with respect to the heat operation within the heated radiation exposure station 376 can be used for the baking operation within the bake station 576. The heating means within the heated radiation exposure station 376 and the baking operation within the bake station 576 can be the identical or substantially different from each other. FIG. 16 illustrates a resistive heating element 1422 within the substrate chuck 333 and a radiative heating element 1424 positioned over the substrate chuck 333. The heating means provides heat at a temperature higher than the temperature used for the heated radiation exposure operation. The baking temperature can be at least 200° C. higher than the radiation exposure temperature. The baking temperature can be at least 300° C., at least 325° C., or at least 350° C. The baking temperature should not be so high as to cause significant decomposition or another adverse effect to the baked planarization layer 1602. The baking temperature can be at most 500° C., at most 450° C., or at most 400° C. The baking temperature can be a value between any of the minimum and maximum numbers noted above, for example, in a range from 300° C. to 500° C., 300° C. to 450° C., or 300° C. to 400° C. In a particular implementation, the baking temperature can be in a range from 350° C. to 400° C. The baking temperature, the soak time at the baking temperature, and the monomer in the photocurable composition all can have an effect on the planarization performance of the baked planarization layer 1602. The monomer in the photocurable composition is selected based on at least all of the baking temperature, the soak time at the baking temperature, and the desired planarization performance of the baked planarization layer 1602. The performance of the baked planarization layer 1602 in subsequent processing steps can also depend on the baking temperature, the soak time at the baking temperature, and the monomer in the photocurable composition.

A soak time is the time the substrate 802 and overlying polymer layer is at the baking temperature. The soak time needs to be sufficient to achieve a needed or desired amount of further polymerization or cross-linking, reduce the amount of a volatile component within the polymer layer to a desired amount, or both. The soak time can be at least 0.25 minute, at least 1 minute, or at least 3 minutes. After a long enough time, further exposure to the baking temperature may not sufficiently improve the polymer layer (a sufficient amount of polymerization or cross-linking has occurred, a remaining amount of the volatile component is low enough to not cause a problem during subsequent processing, etc.) or may start to cause an adverse effect, such as roughening the upper surface 1612 of the baked planarization layer 1602, possible delamination of the baked planarization layer 1602 from the substrate 802, or the like. The soak time may be at most 30 minutes, at most 20 minutes, or at most 15 minutes. The soak time can be a value between any of the minimum and maximum numbers noted above, for example, in a range from 0.25 minute to 30 minutes, 1 minute to 20 minutes, or 3 minutes to 15 minutes.

The baking operation can be performed using a gas. The gas can include a material that is relatively inert to the photocured planarization layer 1502 and the baked planarization layer 1602. The material can include N₂, CO₂, a noble gas (Ar, He, or the like), or a mixture thereof. The gas may not include an oxidizing material, for example O₂, O₃, N₂O, or the like, or may include no more than 2 mol % or no more than 0.5 mol % of the oxidizing material.

As illustrated, the post-exposure bake stations 576 are configured to process a single substrate at a time. In another implementation, the post-exposure bake stations 576 can be configured to process a plurality of substrates during the same baking operation. The post-exposure bake stations 576 may include a cassette or another suitable substrate container or be capable of receiving the cassette or the other suitable substrate container, where the cassette or the other suitable substrate container can hold a plurality of substrates.

The memory 552, a database, or another memory outside the apparatus 500 can include information regarding the composition of or polymer precursor used to form the photocured planarization layer, a desired baking temperature, or a desired soak time to form the baked planarization layer 1602. Referring to FIG. 5, the controller 550 or a local controller can transmit a signal for the post-exposure bake station 576 to flow the inert gas within the post-exposure bake station 576 and control the heating means to maintain the substrate 802 and the photocured planarization layer 1502 at or within an allowable tolerance of the desired baking temperature for the soak time. Referring to FIG. 16, during heating, the controller 550 or a local controller can receive temperature data from a temperature sensor 1632 or 1634 and transmit a signal that is received by the controller 550 or a local controller so that the controller 550 or the local control can transmit a signal for the heating means, such as the resistive heating element 1622 or the radiative heat element 1624, to heat the substrate 802 and the photocured planarization layer 1102 to the baking temperature or to maintain the temperature within the post-exposure bake station 576 at the baking temperature. The allowable tolerance may be +/−10° C., +/−5° C., or +/−2° C. of the desired baking temperature. After the soak time, the controller 550 or a local controller can transmit a signal for the substrate transfer tool 510 to remove the substrate 802 and baked planarization layer 1602 from the post-exposure bake station 576. The substrate 802 and baked planarization layer 1602 can be moved by the substrate transfer tool 510 to a chill plate to reduce the temperature of the substrate 802 and the baked planarization layer 1602 before the substrate 802 and baked planarization layer 1602 are moved back to the substrate pod 571. After chilling is completed, the controller 550 or a local controller can transmit signal for the substrate 802 and baked planarization layer 1602 to be moved to the substrate pod 571.

After reading this specification, skilled artisans will appreciate that many system configurations and processing options are available without deviating from the concepts described herein. Skilled artisans will be able to determine a particular system configuration and a particular method to use to meet the needs or desires for a particular application.

The process described above can be used in forming a planarization layer from a photocurable composition. The process described above can be integrated as part of a manufacturing method of making an article. The article can be an electrical circuit element, an optical element, a microelectromechanical system (MEMS), a recording element, a sensor, a mold, an integrated circuit, or the like. The integrated circuit may be a solid state memory (such as a dynamic random access memory (DRAM), a static random access memory (SRAM), a flash memory, and a magnetoresistive random access memory (MRAM)), a microprocessor, a microcontroller, a graphics processing unit, a digital signal processor, a field programmable gate array (FPGA) or a semiconductor element, a power transistor, a charge coupled-device (CCD), an image sensor, or the like.

The method can further include subjecting the substrate 802 and the baked planarization layer 1602 to other processes for device (article) fabrication, including, for example, curing, oxidation, layer formation, deposition, doping, planarization, lithography, etching, formable material removal, dicing, bonding, and packaging, and the like. The substrate may be processed to produce a plurality of articles (devices), for example, the substrate may be a semiconductor wafer.

### EXAMPLES

Examples described below are provided to demonstrate that a thickness change of a layer formed from a photocurable composition can be affected by a temperature of the photocurable composition during exposure to actinic radiation. The examples are to aid in the understanding of the concepts described herein and not to limit the scope of the invention as defined in the appended claims. In the Examples, values for thickness changes are rounded off to the nearest tenth of a percent.

Six sample sets were prepared and included substrates having an elevational difference between projections and recessions of 100 nm+/−5 nm. The photocurable composition included 90 wt % to 97 wt % of a vinyl benzene and 2.0 wt % to 7.0 wt % of an Irgacure-brand photoinitiator, and may include one, both, or none of a surfactant and a solvent. The wt % values are based on the total weight of the photocurable composition, and the sum of the wt % values is 100 wt %. The exposure to actinic radiation was performed using UV light at an areal power density in a range from 35 to 50 mW/cm², and the photocured planarization layer formed from the photocured planarization layer was baked at a temperature in a range from 350° C. to 400° C. for a soak time in a range of 1.5 to 3.0 minutes. While ranges of values are recited above, all substrates were processed with the same photocurable composition, and the same areal power density, baking temperature, and soak time setpoints. The actual areal power density, baking temperature, and soak time may insignificantly vary due to reproducibility limits of processing equipment.

Table 4 below includes a list of the sample sets and radiation exposure conditions. A superstrate was in contact with the photocurable composition during Step 1 and removed before Step 2. Referring to FIGS. 3 and 4, Step 1 is performed in the radiation exposure station 326 in unit 301, and Step 2 is performed in the radiation exposure station 376 in unit 303. Room temperature is 23° C.

TABLE 4
Samples and Radiation Exposure Conditions

| Sample Set | Step 1 Conditions | Step 2 Conditions |
|---|---|---|
| 1-Step 23° C. | Expose at 23° C. | Not applicable |
| | for the Total Dose | |
| 1-Step 50° C. | Expose at 50° C. | Not applicable |
| | for the Total Dose | |
| 23° C. | Expose at 23° C. to | Expose at 23° C. for the |
| | a dose of 1.5 J/cm² | remainder of the Total Dose |
| 30° C. | Expose at 23° C. to | Expose at 30° C. for the |
| | a dose of 1.5 J/cm² | remainder of the Total Dose |
| 40° C. | Expose at 23° C. to | Expose at 40° C. for the |
| | a dose of 1.5 J/cm² | remainder of the Total Dose |
| 50° C. | Expose at 23° C. to | Expose at 50° C. for the |
| | a dose of 1.5 J/cm² | remainder of the Total Dose |

For the 23° C., 30° C., 40° C., and 50° C. sample sets, dose for Step 2 is the Total Dose minus 1.5 J/cm² from Step 1. Thus, for a Total Dose of 5 J/cm², the dose during Step 2 is 3.5 J/cm²; for a Total Dose of 10 J/cm², the dose during Step 2 is 8.5 J/cm²; for a Total Dose of 15 J/cm², the dose during Step 2 is 13.5 J/cm²; and for a Total Dose of 20 J/cm², the dose during Step 2 is 18.5 J/cm².

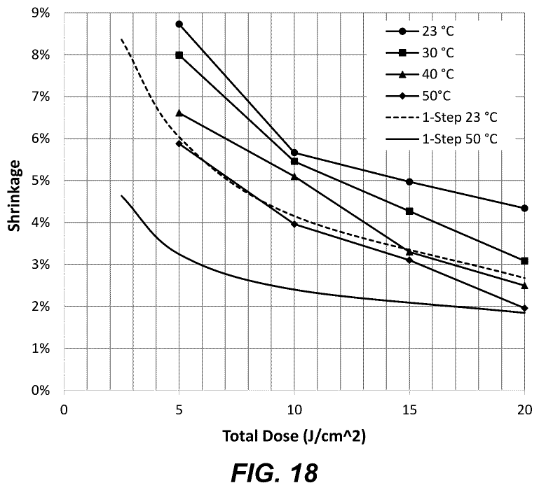

FIG. 18 includes plots of the samples for different Total Doses. For all sample sets, the layer shrunk with processing. Shrinkage in FIG. 18 represent a negative thickness change. A value of shrinkage closer to 0% is desired.

The 1-Step 50° C. sample set provides the best performance with respect to shrinkage. The shrinkage is 1.8% at a Total Dose of 20 J/cm² and is 2.1% at a Total Dose of 15 J/cm². The 1-Step 23° C. (room temperature) sample set did not perform as well as the 1-Step 50° C. sample set. The shrinkage for the 1-Step 23° C. sample set reaches 2.7% at a Total Dose of 20 J/cm².

The 1-Step 50° C. and 1-Step 23° C. can take over 5 minutes to reach a Total Dose of 20 J/cm². The 1-Step 50° C. sample set and the 1-Step 23° C. sample set take too much time to photocure in the radiation exposure station 326 and adversely affects the throughput of unit 301. The other sample sets are photocured for no more than 40 seconds in the radiation exposure station 326. The two-step processes take substantially less time in the radiation exposure station 326 and allow for higher throughput through the system 300.

The 50° C. sample set has a shrinkage of 2.0% at a Total Dose of 20 J/cm². Thus, the 50° C. sample set can achieve approximately the same shrinkage as the 1-Step 50° C. sample set. At Total Doses of 5 J/cm² and 10 J/cm², the shrinkages for the 50° C. sample set and the 1-Step 23° C. sample set are approximately the same. The 40° C. sample set has a shrinkage of 2.5% at a Total Dose of 20 J/cm². The 30° C. sample set has a shrinkage of 3.1% at a Total Dose of 20 J/cm². The substrates and partly cured planarization layers are heated for the radiation exposure at Step 2 for the 50° C. sample set, the 40° C. sample set, and the 30° C. sample set.

For the radiation exposure at Step 2, the 23° C. sample set is at room temperature and is not heated. The 23° C. sample set has a shrinkage of 4.3% at a Total Dose of 20 J/cm². The two-step process where Step 2 is performed at room temperature can be unacceptable for too much shrinkage. For example, an upper limit for shrinkage is 4% for a substrate having an elevational difference of 200 nm and the dimensional change along the baked planarization layer (D₄₈ in Equation 2) is limited to 8 nm.

The samples do not limit the scope of the invention as defined by the appended claims. The heated radiation exposure may be performed at a temperature higher than 50° C., such as 60° C., 80° C., 95° C., or another temperature higher than room temperature.

Embodiments as described herein can achieve higher manufacturing volume and still maintain low thickness changes when forming a planarization layer using an IAP process. In an implementation, a pre-cured layer of a photocurable composition can be exposed to actinic radiation when the pre-cured layer is at room temperature to form a partly cured planarization layer, and the partly cured planarization layer can be exposed to actinic radiation at another temperature to form a photocured planarization layer. The photocured planarization layer can be baked to form a baked planarization layer. High throughput can be achieved by the exposing to actinic radiation at room temperature for a relatively shorter time within a station for radiation exposure, and the heated radiation exposure for a relatively longer time within the heated radiation exposure station can help to reduce the amount of thickness change, such as shrinkage, between a pre-cured layer and its corresponding baked planarization layer.

Note that not all of the activities described above in the general description or the examples are required, that a portion of a specific activity may not be required, and that one or more further activities can be performed in addition to those described. Still further, the order in which activities are listed is not necessarily the order in which they are performed.

Benefits, other advantages, and solutions to problems have been described above with regard to specific implementations. However, the benefits, advantages, solutions to problems, and any feature(s) that can cause any benefit, advantage, or solution to occur or become more pronounced are not to be construed as a critical, required, or essential feature of any or all the claims.

The specification and illustrations of the implementations described herein are intended to provide a general understanding of the structure of the various implementations. The specification and illustrations are not intended to serve as an exhaustive and comprehensive description of all of the elements and features of apparatus and systems that use the structures or methods described herein. Separate implementations can also be provided in combination in a single implementation, and conversely, various features that are, for brevity, described in the context of a single implementation, can also be provided separately or in any subcombination. Further, reference to values stated in ranges includes each and every value within that range. Many other implementations can be apparent to skilled artisans only after reading this specification. Other implementations can be used and derived from the disclosure, such that a structural substitution, logical substitution, or another change can be made without departing from the scope of the disclosure. Accordingly, the disclosure is to be regarded as illustrative rather than restrictive.

What is claimed is:

1. A method, comprising:
exposing a photocurable composition to a first actinic radiation at a first temperature; and
exposing the photocurable composition to a second actinic radiation at a second temperature to form a cured planarization layer, wherein the second temperature is greater than an ambient temperature and different from the first temperature.

2. The method of claim 1, further comprising:
dispensing the photocurable composition onto a substrate,
wherein exposing the photocurable composition to the first actinic radiation is performed such that the photocurable composition is disposed between the substrate and a superstrate.

3. The method of claim 2, further comprises removing the superstrate after exposing the photocurable composition to the first actinic radiation and before exposing the photocurable composition to the second actinic radiation.

4. The method of claim 1, wherein exposing the photocurable composition to the first actinic radiation and exposing the photocurable composition to the second actinic radiation is performed such that the second temperature is greater than the first temperature.

5. The method of claim 1, further comprising:
baking the cured planarization layer to form a baked planarization layer, wherein:
exposing the photocurable composition to the first actinic radiation is performed for a first radiation dose,
exposing the photocurable composition to the second actinic radiation is performed for a second radiation dose, and
a thermal shrinkage of the baked planarization layer is less than a thermal shrinkage of a different baked planarization layer formed from the photocurable composition by exposing the photocurable composition to a single radiation dose at the ambient temperature, followed by the baking at a baking temperature and a soak time, wherein the single radiation dose is a sum of the first radiation dose and the second radiation dose.

6. The method of claim 5, wherein baking the cured planarization layer is performed at the baking temperature in a range from 300° C. to 500° C. and the soak time in a range from 1 minute to 60 minutes.

7. The method of claim 1, wherein the photocurable composition comprises a polymerizable material that includes an aryl group.

8. The method of claim 7, wherein the polymerizable material includes a vinyl benzene.

9. The method of claim 1, wherein exposing the photocurable composition to the second actinic radiation is performed in an ambient that includes at most 2 mol % of an oxygen-containing gas.

10. The method of claim 1, wherein:
exposing the photocurable composition to the first actinic radiation is performed at a first radiation dose,
exposing the photocurable composition to the second actinic radiation is performed at a second radiation dose, and
the first radiation dose is at most 30% of a sum of the first radiation dose and the second radiation dose.

11. A method, comprising:
exposing a photocurable composition to a first actinic radiation, wherein the photocurable composition is positioned between a substrate and a superstrate;
removing the superstrate from the photocurable composition; and
exposing the photocurable composition to a second actinic radiation to form a cured planarization layer,
wherein removing the superstrate is performed after exposing the photocurable composition to the first actinic radiation and before exposing the photocurable composition to the second actinic radiation.

12. The method of claim 11, further comprising:
baking the cured planarization layer to form a baked planarization layer.

13. The method of claim 12, wherein baking the cured planarization layer is performed at a baking temperature of at least 300° C. and a soak time of at least 1 minute.

14. The method of claim 13, wherein baking the cured planarization layer is performed at the baking temperature of at most 500° C. and the soak time of at most 60 minutes.

15. The method of claim 13, wherein:
exposing the photocurable composition to the first actinic radiation is performed for a first radiation dose,
exposing the photocurable composition to the second actinic radiation is performed for a second radiation dose, and
a thermal shrinkage of the baked planarization layer is less than a thermal shrinkage of a different baked planarization layer formed from the photocurable composition by exposing the photocurable composition to a single radiation dose at an ambient temperature, followed by baking at the baking temperature and the soak time, wherein the single radiation dose is a sum of the first radiation dose and the second radiation dose.

16. The method of claim 11, wherein:
exposing the photocurable composition to the first actinic radiation is performed at a first temperature,
exposing the photocurable composition to the second actinic radiation is performed at a second temperature, and
the second temperature is greater than the first temperature.

17. A system, comprising:
a first radiation exposure station including a first actinic radiation source configured to emit a first actinic radiation at a first wavelength less than 700 nm to expose a photocurable composition that is disposed between a substrate and a superstrate;
a superstrate removal tool to remove the superstrate from the photocurable composition;
a second radiation exposure station located remotely with respect to the first radiation exposure station, wherein the second radiation exposure station includes:
a second actinic radiation source configured to emit a second actinic radiation at a second wavelength less than 700 nm to expose the photocurable composition and form a cured planarization layer; and
a heating means for heating the photocurable composition and the substrate to a radiation exposure temperature; and
a controller configured to:
activate the superstrate removal tool to remove the superstrate after a first radiation exposure within the first radiation exposure station and before a second radiation exposure within the second radiation exposure station; and
control the heating means to heat the photocurable composition and the substrate to the radiation exposure temperature that is greater than an ambient temperature.

18. The system of claim 17, further comprising:
a dispense head configured to dispense the photocurable composition over the substrate.

19. The system of claim 18, wherein:
a first unit includes the dispense head, the superstrate removal tool, and the first radiation exposure station, and
a second unit includes the second radiation exposure station, wherein the second unit is different and spaced apart from the first unit.

20. The system of claim 17, further comprising:
a bake station configured to heat the cured planarization layer to form a baked planarization layer, wherein the bake station is configured to heat the substrate and the cured planarization layer to a baking temperature in a range from 300° C. to 500° C.
